(19) United States
(12) Patent Application Publication
(10) Pub. No.: US 2022/0220989 A1
(43) Pub. Date: Jul. 14, 2022

(54) FASTENER FOR COMPONENTS IN ELECTRONIC DEVICE

(71) Applicant: 3M INNOVATIVE PROPERTIES COMPANY, St. Paul, MN (US)

(72) Inventors: Dylan T. Cosgrove, Oakdale, MN (US); Michael R. Gorman, Woodbury, MN (US); Mary M. Caruso Dailey, Maplewood, MN (US); Scott R. Kaytor, Woodbury, MN (US)

(21) Appl. No.: 17/613,215

(22) PCT Filed: May 21, 2020
(86) PCT No.: PCT/IB2020/054863

§ 371 Date: Nov. 22, 2021

Related U.S. Application Data
(60) Provisional application No. 62/851,937, filed on May 23, 2019.

(51) Int. Cl. F16B 5/07; F16B 11/00; H05K 7/14

(52) U.S. Cl. CPC F16B 5/07; H05K 7/14; F16B 11/006

(57) ABSTRACT

Thin, reworkable fastener system for securing electronic components. The fastener system includes two strips of fastener tapes (1), each including a pattern of fastening elements (4,6) that mechanically interengage when pressed into one another, creating a mechanical bond.

### BACKGROUND

Batteries, logic boards, and other components are typically secured in portable electronic devices by two-sided adhesive coated foam tapes, adhesives, or mechanical fasteners such as screws. When tapes are used, they are typically thin, thus very minimally contributing to overall device thickness. When components are set into an electronic device, however, mistakes in placement or even a bad component discovered later in the manufacturing process can necessitate removal of the component from the chassis or de-coupling it from other parts. Double-sided tapes are generally inexpensive and durable, but subsequent removal of a component coupled with such tape is difficult or impractical and may damage the electronic device's chassis or the component bonded to the chassis.

Fasteners are used in a variety of applications, including construction, machinery, medical equipment, automobile assembly, personal care products, and the textile industry. Commonly known fasteners range from rivets, snaps and buttons to hook and loop fasteners, each of which involve joining unlike components (e.g., male and female components) for assembling two articles together. Some fasteners, which are sometimes called self-mating fasteners or hook-and-hook fasteners, are composed of interlocking members that do not include male and female components. For assembling two articles together, each fastening member is attached to a surface of its respective article, and the two articles are joined together when the fastening members are mated.

Certain fasteners have been reported that include different structures on the same fastening member. See, for example, U.S. Pat. No. 5,586,372 (Eguchi); U.S. Pat. No. 5,884,374 (Clune); U.S. Pat. No. 6,276,032 (Nortman); and U.S. Pat. No. 6,546,604 (Galkiewicz). Such fasteners can be used in containers for various consumer goods such as dry goods, food such as potato chips and cheese, animal food, lawncare products, etc.

### SUMMARY

The present disclosure provides very thin, releasably fastenable fastening systems. Electronic systems, particularly handheld consumer devices such as smart phones, may incorporate such thin fastening systems to secure electronic components, such as batteries, in a chassis. The releasably fastenable fastening systems have a total mated thickness of around 250 μm (or between 200 and 400 μm). The closure systems disclosed herein are self-mating.

In one aspect, an electronic device having a component secured with a thin fastening system according to the disclosure is described. In a further aspect, a thin fastening system is described. In a further aspect, a component of a thin fastening system is described.

All headings provided herein are for the convenience of the reader and should not be used to limit the meaning of any text that follows the heading, unless so specified.

The terms “comprises” and variations thereof do not have a limiting meaning where these terms appear in the description and claims. Such terms will be understood to imply the inclusion of a stated step or element or group of steps or elements but not the exclusion of any other step or element or group of steps or elements.

Terms such as “a”, “an” and “the” are not intended to refer to only a singular entity, but include the general class of which a specific example may be used for illustration. The terms “a”, “an”, and “the” are used interchangeably with the term “at least one”.

The phrase “comprises at least one of” followed by a list refers to comprising any one of the items in the list and any combination of two or more items in the list. The phrase “at least one of” followed by a list refers to any one of the items in the list or any combination of two or more items in the list.

As used herein, the term “or” is generally employed in its usual sense including “and/or” unless the content clearly dictates otherwise.

The term “and/or” means one or all of the listed elements or a combination of any two or more of the listed elements.

The term “machine direction” (MD) as used herein denotes the direction of a running web of material during a manufacturing process. When a strip is cut from a continuous web, the dimension in the machine direction corresponds to the length “L” of the strip. The terms “machine direction” and “longitudinal direction” may be used interchangeably. The term “cross-machine direction” (CD) as used herein denotes the direction which is essentially perpendicular to the machine direction. When a strip is cut from a continuous web, the dimension in the cross-machine direction corresponds to the width “W” of the strip. Accordingly, the term “width” typically refers to the shorter dimension in the plane of the first surface of the backing, which is the surface bearing the rail segments and posts. As used herein the term “thickness” usually refers to the smallest dimension of the fastener, which is the dimension perpendicular to the first surface of the backing.

The term “alternating” as used herein refers to one row of rail segments being disposed between any two adjacent rows of posts (i.e., the rows of posts have only one row of rail segments between them) and one row of posts being disposed between any two adjacent rows of rail segments.

The term “perpendicular” as used herein to refer to the relationship between the backing and the rail segments and/or posts includes substantially perpendicular. “Substantially perpendicular” means that the planes defined by the backing and a row of rail segments or posts can deviate from perpendicular by up to 10 (in some embodiments, up to 7.5 or 5) degrees.

As used herein in connection with a measured quantity, the term “about” refers to that variation in the measured quantity as would be expected by the skilled artisan making the measurement and exercising a level of care commensurate with the objective of the measurement and the precision of the measuring equipment used. Herein, “up to” a number (e.g., up to 50) includes the number (e.g., 50).

All numerical ranges are inclusive of their endpoints and nonintegral values between the endpoints unless otherwise stated (e.g., 1 to 5 includes 1, 1.5, 2, 2.75, 3, 3.80, 4, 5, etc.).

These and other aspects of the present disclosure will be apparent from the detailed description below. In no event, however, should the above summaries be construed as limitations on the claimed subject matter, which subject matter is defined solely by the attached claims, as may be amended during prosecution.

### BRIEF DESCRIPTION OF THE DRAWINGS

The disclosure may be more completely understood in consideration of the following detailed description of various embodiments of the disclosure in connection with the accompanying drawings, in which:

FIG. 1A is a schematic perspective view of an embodiment of a fastener of the present disclosure.

FIG. 1B is a schematic side view of the fastener of FIG. 1A.

FIG. 1C is a schematic side view of the fastener of FIG. 1A, which side view is orthogonal to the side view shown in FIG. 1B.

FIG. 2A is a schematic perspective view of another embodiment of a fastener of the present disclosure.

FIG. 2B is a schematic side view of the fastener of FIG. 2A.

FIG. 2C is a schematic side view of an embodiment of a fastening system of the present disclosure in which both fastening members include the fastener of FIGS. 2A and 2B.

FIG. 3A is a schematic side view of an embodiment of fastener of the present disclosure undergoing deformation during fastening, with strain calculated by Finite Element Modeling depicted by shading.

FIG. 3B is a schematic side view of the fastener of FIG. 3A after fastening, with residual strain calculated by Finite Element Modeling depicted by shading.

FIG. 4 is a schematic side view of a fastener not according to the present disclosure, with permanent plastic deformation after fastening calculated by Finite Element Modeling depicted by shading.

FIG. 5 is a schematic front plan view of one embodiment of a reclosable package.

FIG. 6 is a schematic rear plan view of the reclosable package of FIG. 5.

FIG. 7 is a schematic top perspective view of the reclosable package of FIG. 5.

FIG. 8 is a schematic cross-section view of a portion of the reclosable package of FIG. 5 with an embodiment of the fastener of the present disclosure disposed in a closed configuration.

FIG. 9 is a schematic cross-section view of a portion of the reclosable package of FIG. 5 with an embodiment of the fastener of the present disclosure disposed in an open configuration with the upper seal region still intact.

FIG. 10 is a schematic cross-section view of a portion of the reclosable package of FIG. 5 with an embodiment of the fastener of the present disclosure disposed in the open configuration.

FIG. 11 is a schematic cross-section view an embodiment of the opening of the reclosable package of FIG. 5 when the fastener is in the closed configuration.

FIG. 12 is a schematic perspective view of another embodiment of a reclosable package.

FIG. 13 is a schematic front plan view of the reclosable package of FIG. 11.

FIG. 14 is a schematic perspective view of another embodiment of a reclosable package.

FIG. 15 is a schematic front plan view of the reclosable package of FIG. 13.

FIG. 16 is a perspective view of one embodiment of an apparatus and method used to form a reclosable package.

FIG. 17 is a photo micrograph of the fastener made in Example 2.

FIG. 18 is a drawing of an electronic device and a component to be fastened in the device.

FIG. 19 is a drawing of the profile view of a cut-away of the electronic device of FIG. 18, showing the fastening system stack.

### DETAILED DESCRIPTION

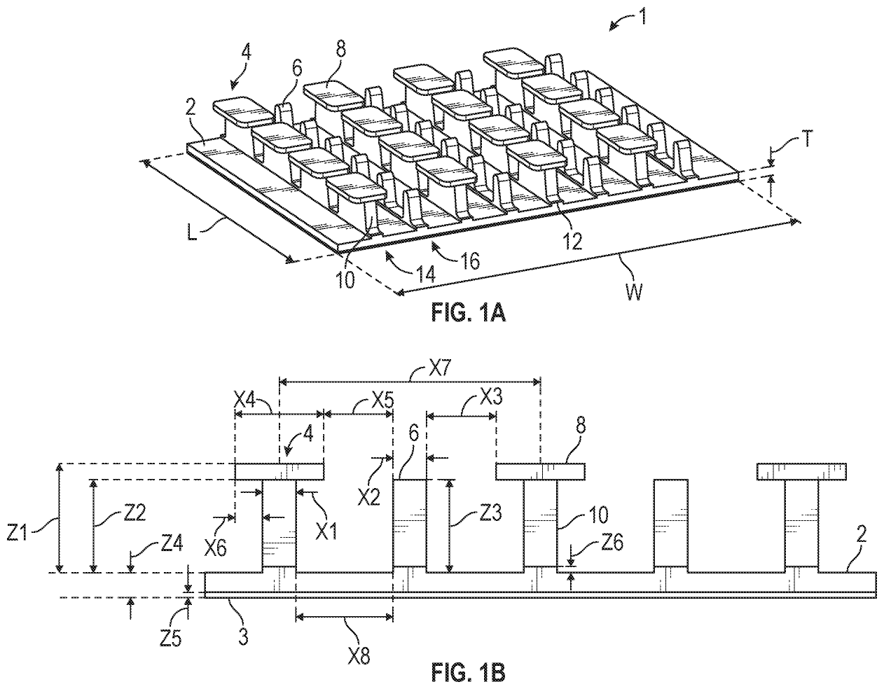

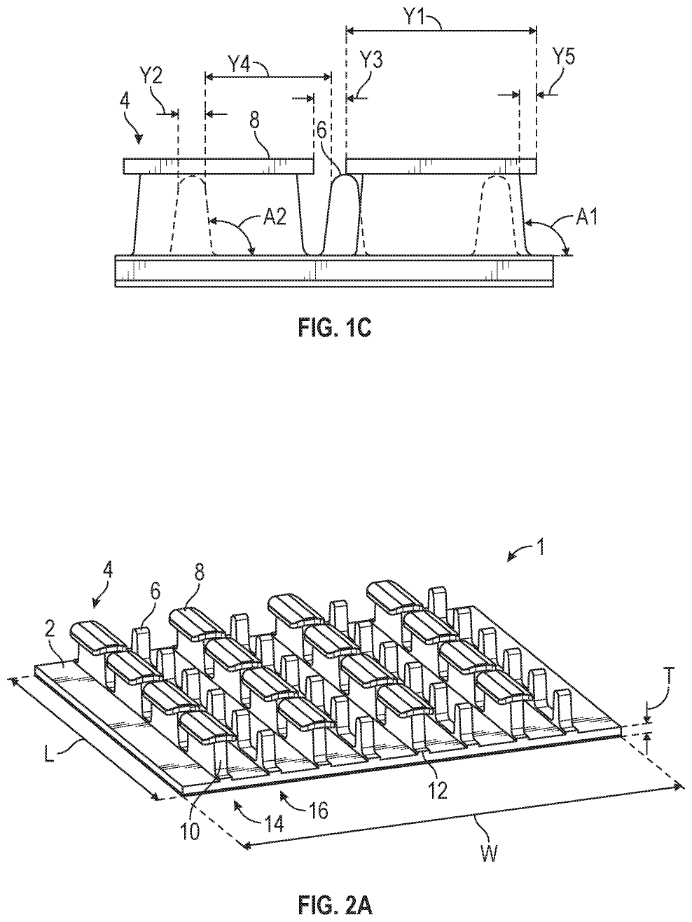

An embodiment of a fastener of the present disclosure is shown in FIGS. 1A, 1B, and 1C. Fastener 1 includes a backing 2 having a length (l), a width (w), and a thickness (t). Fastener 1 includes rows 14 of rail segments 4. In the embodiment illustrated in FIGS. 1A, 1B, and 1C, the rail segments 4 protrude perpendicularly from the backing 2. Each of the rail segments 4 has a base portion 10 attached to the backing 2 and a cap portion 8 distal from the backing 2. The cap portion 8 has a cap width X4 that is greater than the width X1 of the base portion 10, and the cap portion 8 overhangs the base portion 10 on opposing sides. The ratio of the cap width X4 to the width X1 of the base portion 10 is typically at least 1.25:1, 1.5:1, or 2:1 and can be up to 3:1, 4:1, or 5:1. FIG. 1B illustrates the cap overhang distance X6. In some embodiments, the cap portion 8 overhangs the base portion 10 on all sides of base portion 10. FIG. 1C illustrates the cap overhang distance Y5, in the direction parallel to the length (l) of the fastener 1. Caps also have a cap thickness, which, if the cap is not rectilinear, is measured as a distance between a line tangent to the highest point on the cap above the backing and a line tangent to lowest point on the cap above the backing. For example, in the embodiment shown in FIG. 1B, the cap thickness is Z1 minus Z2. From the term “rows of rail segments”, it should be understood that each row 14 includes more than one rail segment 4. The fastener 1 does not include a continuous rail; instead the rail segments 4 are separated from each other on the backing 2. For example, the caps 8 of the rail segments 4 in a row 14 are separated by cap-to-cap distance Y3 in the direction parallel to the length (l) of the fastener 1.

The base portion 10 of the rail segment 4 has a length Y1 that is greater than the width X1 of the base portion 10. In some embodiments, the ratio of the length Y1 to the width X1 of the base portion 10 is at least about 1.5:1, 2:1, 3:1, 4:1, or 5:1, 10:1, or 15:1. The base portion 10 of the rail segment 4 may have a variety of cross-section shapes. For example, the cross-sectional shape of the base portion 10 may be a polygon (e.g., rectangle, hexagon, or octagon), or the cross-sectional shape of the base portion 10 may be curved (e.g., elliptical). The base portion 10 may taper from its base to its distal end. In this case and in the case of curved base portions, the ratio of the length Y1 to the width X1 of the base portion 10 is measured from the longest and the widest point. As shown in FIG. 1B the length Y1 of the base portion at its longest point is about the same as the length of the cap portion.

For embodiments such as the embodiment illustrated in FIG. 1C, base portions 10 that taper from their bases to their distal ends have a sloping face and a taper angle A1 between the sloping face and the backing 2. In some embodiments, the taper angle A1 between the sloping face of the base portion 10 and the backing 2 is in a range from 91 degrees to 130 degrees, in some embodiments, in a range from 91 degrees to 125 degrees, 95 degrees to 120 degrees, 95 degrees to 115 degrees, 95 degrees to 110 degrees, 93 degrees to 105 degrees, or 95 degrees to 100 degrees.

In some embodiments, the rail segments 4 have a maximum height Z1 (above the backing 2) of up to 3 millimeter (mm), 1.5 mm, or 1 mm and, in some embodiments, a minimum height of at least 0.1 mm or 0.2 mm. The height Z1 of the rail segments 4 can be in a range from 0.3 mm to 0.7 mm, 0.3 mm to 0.6 mm, or 0.35 mm to 0.55 mm. The thickness Z7 of the cap portion 8 of rail segments 4 can be in a range from 0.03 mm to 0.3 mm, 0.04 mm to 0.15 mm, or 0.04 mm to 0.1 mm. In some embodiments, the base portions 10 of the rail segments 4 have a maximum width X1 of up to about 0.5 mm, 0.4 mm, 0.3 mm, or 0.2 mm and a minimum width of at least 0.05 mm, 0.1 mm, or 0.125 mm. Some useful widths X1 of the base portions 10 are in a range from 0.05 mm to 0.5 mm, 0.1 mm to 0.2 mm, or 0.125 mm to 0.175 mm. Some useful cap widths X4 of the rail segments 4 are in a range from 0.1 mm to 1.0 mm, 0.3 mm to 0.5 mm, 0.3 mm to 0.45 mm, or 0.3 mm to 0.4 mm. Some useful cap overhang distances X6 of the rail segments 4 are in a range from 0.025 mm to 0.4 mm, 0.05 mm to 0.3 mm, or 0.1 m to 0.25 mm. In some embodiments, the rail segments 4 have a maximum length Y1 of up to about 1.5 mm (in some embodiments, up to 1.25, 1.0, 0.9, or 0.8) mm and a minimum length Y1 of at least about 0.1 mm, 0.2 mm, 0.4 mm, or 0.5 mm. The length Y1 of the rail segments can be in a range from 0.1 mm to 1.5 mm, 0.2 mm to 1.0 mm, or 0.600 mm to 0.800 mm. Some useful cap overhang distances Y5 of the rail segments 4 in the length direction are in a range from 0.025 mm to 0.2 mm, 0.025 mm to 0.1 mm, or 0.04 mm to 0.075 mm. In some embodiments, the cap-to-cap distance Y3 in the direction parallel to the length (l) of the fastener 1 is up to about 0.5 mm, 0.4 mm, 0.3 mm, or 0.25 mm and at least about 0.05 mm, 0.1 mm, or 0.125 mm. Some useful cap-to-cap distances Y3 are in a range from 0.05 mm to 0.5 mm, 0.1 mm to 0.3 mm, or 0.125 mm to 0.225 mm.

The fastener of the present disclosure typically also comprises rows of posts. In the embodiment illustrated in FIGS. 1A, 1B, and 1C, the fastener 1 includes rows 16 of posts 6 protruding perpendicularly from the backing 2. In some embodiments, the rows 14 of rail segments 4 and rows 16 of posts 6 alternate. The fastener 1 can have at least 2, 3, 5, or 10 of the rows 14 of rail segments 4 alternating with at least 2, 3, 5, or 10 of the rows 16 of posts 6. From the term “rows of posts”, it should be understood that each row 16 includes more than one post 6. The fastener 1 does not include a continuous ridge; instead the posts 6 are separated from each other on the backing 2. For example, the posts 6 in a row 16 are separated by a distance Y4 in the direction parallel to the length (l) of the fastener 1. In general, the posts have a length that is different from the length of the rail segments. In the embodiment illustrated in FIGS. 1A, 1B, and 1C, the length Y1 of the base portion 10 of the rail segments 4 is greater than the length Y2 of the post 6, and the number of posts 6 in one of the rows 16 of posts is more than the number of rail segments 4 in one of the rows of rail segments 14. The length Y1 of the base portion 10 of the rail segments 4 can be at least two, three, or four times the length Y2 of the posts 6. The number of posts 6 in one of the rows 16 of posts can be at least 1.5, 2, or 3 times the number of rail segments 4 in one of the rows of rail segments 14. Since the fastener 1 is useful as a self-mating fastener, the posts generally have a height that is no greater than a height of the rail segments. In the embodiment illustrated in FIGS. 1A, 1B, and 1C, the height Z3 of the posts 6 is less than the height Z1 of the rail segments 4. In some embodiments, the height Z3 of posts 6 is up to 95, 90, 80, 75, or 70 percent of the height Z1 of the rail segments 4.

Posts useful in the fastener of the present disclosure may have a variety of cross-sectional shapes in a plane parallel to the backing. For example, the cross-sectional shape of the post may be a polygon (e.g., square, rectangle, rhombus, hexagon, pentagon, or dodecagon), which may be a regular polygon or not, or the cross-sectional shape of the post may be curved (e.g., round or elliptical). In some embodiments, the post has a base attached to the backing and a distal tip, and the distal tip has a cross-sectional area that is less than or equal to a cross-sectional area of the base. The post may taper from its base to its distal tip, but this is not a requirement. In some embodiments, the post has a distal cap with a cap width that is greater than the width of the base. The cap can overhang the base on opposing sides or may overhang the base on all sides. Capped posts useful in the fastener of the present disclosure can have a variety of useful shapes including a mushroom (e.g., with a circular or oval head enlarged with respect to the stem), a nail, a T, or a golf tee.

Referring again to FIGS. 1A, 1B, and 1C, in some embodiments, posts 6 useful in the fastener of the present disclosure have a maximum width X2 of up to about 0.5 mm, 0.4 mm, 0.3 mm, or 0.2 mm and a minimum width of at least 0.05 mm, 0.1 mm, or 0.125 mm. Some useful widths X2 of the posts 6 are in a range from 0.05 mm to 0.5 mm, 0.1 mm to 0.2 mm, or 0.125 mm to 0.175 mm. In some embodiments, posts 6 useful in the fastener of the present disclosure have a maximum length Y2 of up to about 0.5 mm, 0.4 mm, 0.3 mm, or 0.2 mm and a minimum width of at least 0.05 mm, 0.1 mm, or 0.125 mm. Some useful widths Y2 of the post 6 are in a range from 0.05 mm to 0.5 mm, 0.1 mm to 0.2 mm, 0.1 mm to 0.15 mm, or 0.125 mm to 0.175 mm. In some embodiments, the distance Y4 between posts 6 in the direction parallel to the length (l) of the fastener 1 is up to about up to about 1.5 mm (in some embodiments, up to 1.25, 1.0, 0.9, or 0.8) mm and at least about 0.1 mm, 0.2 mm, or 0.4 mm. The distance Y4 between posts 6 can be in a range from 0.1 mm to 1.5 mm, 0.2 mm to 1.0 mm, or 0.400 mm to 0.600 mm.

For embodiments such as the embodiment illustrated in FIG. 1C, posts 6 that taper from their bases to their distal tips have a sloping face and a taper angle A2 between the sloping face and the backing 2. In some embodiments, the taper angle A2 between the sloping face of the post 6 and the backing 2 is in a range from 91 degrees to 130 degrees, in some embodiments, in a range from 91 degrees to 125 degrees, 91 degrees to 120 degrees, 91 degrees to 115 degrees, 91 degrees to 110 degrees, 91 degrees to 105 degrees, or 95 degrees to 100 degrees.

In some embodiments, the posts 6 have a maximum height Z3 (above the backing 2) of up to 2.85 millimeter (mm), 1.25 mm, or 1 mm and, in some embodiments, a minimum height of at least 0.08 mm or 0.16 mm. The height Z3 of the posts can be in a range from 0.2 mm to 0.6 mm, 0.3 mm to 0.6 mm, 0.3 mm to 0.4 mm, or 0.35 mm to 0.55 mm. In some embodiments, each of the posts has a height to width aspect ratio that is at least 1.5:1, at least 2:1, or at least 3:1. In some embodiments, each of the posts has a height to length aspect ratio that is at least 1.5:1, at least 2:1, or at least 3:1.

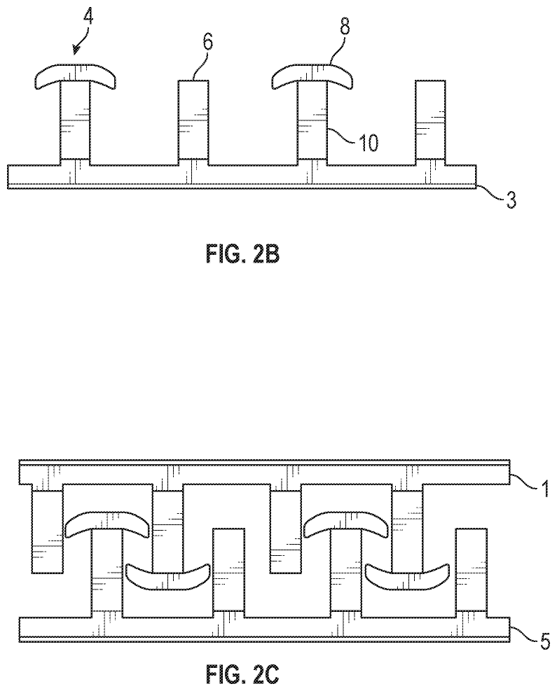

Another embodiment of a fastener of the present disclosure is shown in FIGS. 2A and 2B. In this embodiment, the cap portion 8 of the rail segment 4 has a different shape than the cap portion 8 of the embodiment shown in FIGS. 1A, 1B, and 1C. The features and dimensions of any of the embodiments described above for the fastener shown in FIGS. 1A, 1B, and 1C can be used in combination with the fastener shown in FIGS. 2A and 2B to provide corresponding embodiments.

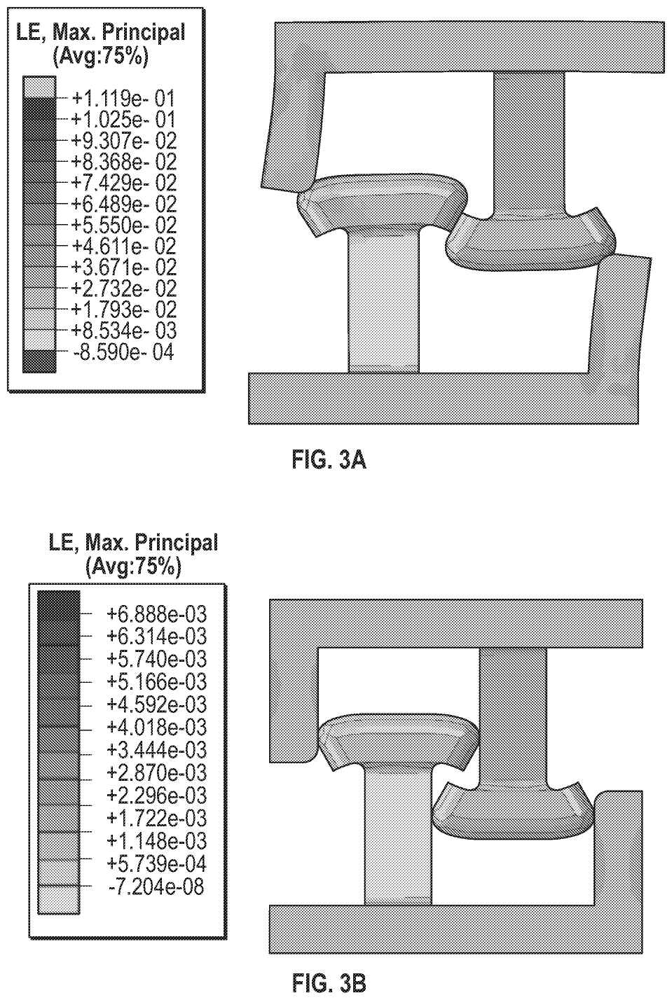

Fastener 1 is useful, for example, as a self-mating fastener. As used herein, self-mating refers to fasteners in which fastening is accomplished by interengaging fastener elements of the same type (e.g., fastening heads). In some embodiments, self-mating refers to fasteners in which fastening is accomplished by interengaging fastener elements of identical shape. In some embodiments, self-mating refers to the ability for the fastener to engage with itself when it is in a folded configuration, for example, along an axis parallel to either the length (L) or width (W) of the fastener, referring to FIGS. 1A and 2A. Two fastening members (e.g., first and second fastening members (1,5)), each having the structure shown in FIGS. 2A and 2B, for example, can be fastened together in a self-mating engagement as shown in FIG. 2C. In some embodiments, a first fastening member 1 is a fastener of the present disclosure as described above in any of its embodiments, and a second fastening member may include the rail segments but not include the posts. In some embodiments, the first and second fastening members may be different embodiments of the fastener of the present disclosure. For example, the first fastening member 1 may have a cap shape like that shown in FIG. 1A and a second fastening member 5 may have a cap shape like that shown in FIG. 2A. In any of these embodiments, when the first and second fastener members 1, 5 undergo fastening, the posts typically bend away from the rail segments while the cap portions of the rail segments of the first and second fastener members pass by each other as shown in FIG. 3A. The posts then return to their original positions after the first and second fastener members are fastened as shown in FIG. 3B.

Accordingly, in some embodiments, the posts have a lower bending stiffness than that of the rail segments. The bending stiffness k for small strain behavior is determined by the equation k=3EI/H, in which E is the modulus of the material making up the posts and the rail segments, H is the height of the posts or rail segments, and I=W³L/12, in which W is the width and L is the length of the posts or rail segments. In some embodiments, the length of the base portion of the rail segments is greater than a length of the posts. In these embodiments, when the width of the base portion and the width of the posts are similar, the bending stiffness of the rail segments will be higher than the bending stiffness of the posts. Referring again to FIG. 1A, the rows 14 of rail segments 4 can collectively have a higher bending stiffness than rows 16 of posts 6. When there are more posts 6 in a row 16 of posts, the bending stiffness of the posts can be adjusted (e.g., by selection length or width) so that collectively the row 16 of posts 6 has less bending stiffness than a row 14 of rail segments 4. The bending stiffness of each row of rail segments or posts can be determined by the number of rail segments or posts in each row and the bending stiffness of each of the rail segments or posts.

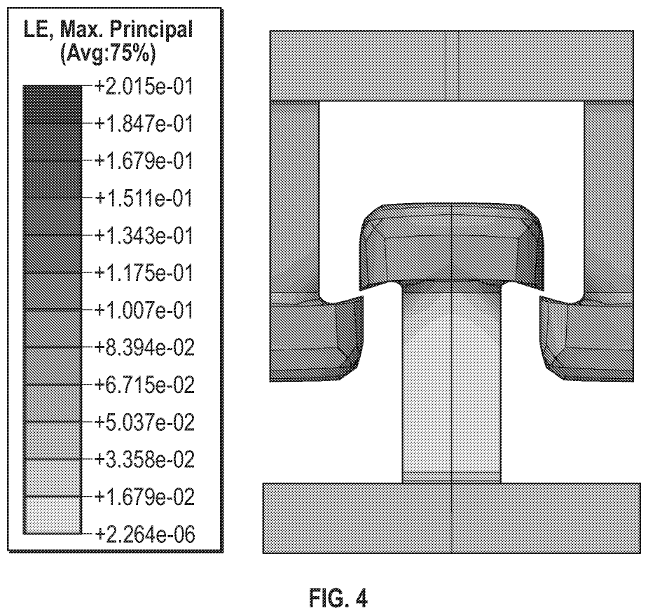

In some embodiments, the fastening system of the present disclosure is releasably fastenable. As used herein, the term “releasably fastenable” means that the fastening members can alternate between the fastened and unfastened configurations one or more times without destroying the functionality of the fastener. Typically and advantageously, the unique structure of the fastener of the present disclosure can allow for multiple cycles of fastening and unfastening without excessive plastic (i.e., irreversible) deformation of the engaging rail segments. As described in detail in the Examples, below, a comparative fastener that includes rail segments but no posts can undergo fastening when the rail segments are pushed against and past one another for interlocking. The cap portions of the rail segments of comparative fastener exhibit a relative high degree of plastic (i.e., irreversible) deformation after such engagement as shown in FIG. 4. The plastic deformation can limit the ability of the comparative fastener to be unfastened and refastened since the shape of the fastener is altered by the first and successive engagements. In contrast, in the fastening system of the present disclosure when the first and second fastener members undergo fastening, the posts undergo elastic deformation while the cap portions of the rail segments of the first and second fastener members pass by each other as shown in FIG. 3A. The cap portions of the rail segments of the fastener of the present disclosure exhibit a relative low degree of plastic (i.e., irreversible) deformation after engagement as shown in FIG. 3B.

Since fastener 1 illustrated in FIGS. 1A to C and 2A to C is useful, for example, as a self-mating fastener, a shortest distance X8 between one of the posts 6 and one of the base portions 10 of the rail segments 4 in adjacent rows 14, 16 is wide enough to allow the insertion of the cap portion 8 of the rail segments 4. Distance X8 may be substantially the same as X4, as described above in any of the embodiment for X4. In some embodiments, distance X8 is within about 20, 15, or 10 percent of the cap width X4. In some embodiments, a ratio of the distance X8 to the width X1 of the base portion 10 is in a range from 2:1 to 5:1 or from 2:1 to 4:1, or the ratio may be about 3:1. Distances X3 and X5 between one of the post 6 and one of the cap portions 8 of the rail segments 4 in adjacent rows 14, 16 is generally smaller than distance X8 since the cap width X4 is wider than the width of the base portion X1. Some useful distances X3 and X5 are in a range from 80 to 800 μm, 100 to 500 μm, 200 to 400 μm, or 200 to 350 μm. Distances X3 and X5 between a post 6 and two adjacent rows of the caps portions 8 of rail segments 4 need not be equal.

In some embodiments, when the first and second fastener members are fastened, they can slide relative to each other in a direction parallel to the length of the backing. This may be advantageous, for example, if the positioning of the first and second fastener members relative to each is not desirable when the first and second fastener members are initially fastened. To achieve a desirable positioning the first and second fastening members can be slid into place.

In some embodiments, when the first and second fastener members are fastened, they cannot slide relative to each other in a direction parallel to the length of the backing (that is, machine direction). Distances of X4 that are 10, 15, 10, 5 or 1 percent larger than X4 enable significant L direction friction force resistance proportional to the values of post and rail thickness, X1 and X2. This feature may be desirable in applications where omni-directional bonding properties are required, such as batteries, logic boards or other components in an electronic device.

The design of rails and posts may also be modified to mechanically restrain slippage or movement in the down-web direction. For example, rail segments 4 could be introduced into the row of posts 6 as shown in FIG. 1a, with the pitch of the regularly repeating post pattern modified to allow coupling with rail segments. Other designs are similarly possible.

The first and second fastening members of a fastening system according to some embodiments of the present disclosure may or may not be connected together. In some embodiments, the first and second fastening members may be connected to two discrete substrates. In some embodiments, the first and second fastening members may be part of the same strip of material in which the first fastening member is folded over to contact the second fastening member.

In the fastener according to the present disclosure, the rail segments, posts, and at least a portion of the backing are integral (that is, generally formed at the same time as a unit, unitary). Fastening elements such as rail segments and upstanding posts on a backing can be made, for example, by feeding a thermoplastic material onto a continuously moving mold surface with cavities having the inverse shape of the fastening elements. The thermoplastic material can be passed between a nip formed by two rolls or a nip between a die face and roll surface, with at least one of the rolls having the cavities. Pressure provided by the nip forces the resin into the cavities. In some embodiments, a vacuum can be used to evacuate the cavities for easier filling of the cavities. The nip has a large enough gap such that a coherent backing is formed over the cavities. The backing may be formed with no holes therethrough. The mold surface and cavities can optionally be air or water cooled before stripping the integrally formed backing and fastening elements from the mold surface such as by a stripper roll.

Suitable mold surfaces for forming fastening elements on a backing include tool rolls such as those formed from a series of plates defining a plurality of cavities about its periphery including those described, for example, in U.S. Pat. No. 4,775,310 (Fischer). Cavities may be formed in the plates by drilling or photoresist technology, for example. Other suitable tool rolls may include wire-wrapped rolls, which are disclosed along with their method of manufacturing, for example, in U.S. Pat. No. 6,190,594 (Gorman et al.). Another example of a method for forming a backing with upstanding fastening elements includes using a flexible mold belt defining an array of fastening element-shaped cavities as described in U.S. Pat. No. 7,214,334 (Jens et al.). Yet other useful methods for forming a backing with upstanding fastening elements can be found in U.S. Pat. No. 6,287,665 (Hammer), U.S. Pat. No. 7,198,743 (Tuma), and U.S. Pat. No. 6,627,133 (Tuma).

If rail segments formed upon exiting the cavities do not have caps, first and second fastening members will not have any closure affinity for each other. Caps can be subsequently formed on the rail segments by a capping method as described in U.S. Pat. No. 5,077,870 (Melbye et al.). Typically, the capping method includes deforming the tip portions of the rail segments using heat and/or pressure. The heat and pressure, if both are used, could be applied sequentially or simultaneously. The formation of rail segments can also include a step in which the shape of the cap is changed, for example, as described in U.S. Pat. No. 6,132,660 (Kampfer) and/or U.S. Pat. No. 6,592,800 (Levitt). For example, one or more of these processes can be useful for changing the shape of the cap portion 8 shown in FIG. 1A to the shape shown in FIG. 2A. The formation of rail segments can also include a step in which the cap is embossed, for example, as described in U.S. Pat. No. 6,000,106 (Kampfer). After one or more of these capping processes, first and second fastening members in a fastening system of the present disclosure can be closed together. The amount of force necessary to close and to peel open the first and second fastening members can be adjusted as desired by tailoring the capping process.

Another useful method for fastening elements on a backing is profile extrusion described, for example, in U.S. Pat. No. 4,894,060 (Nestegard). Typically, in this method a thermoplastic flow stream is passed through a patterned die lip (e.g., cut by electron discharge machining) to form a web having downweb ridges, slicing the ridges, and stretching the web to form separated fastening elements. The ridges may be considered precursors to the fastening elements and exhibit the cross-sectional shape of the rail segments and posts to be formed. The ridges are transversely sliced at spaced locations along the extension of the ridges to form discrete portions of the ridges having lengths in the direction of the ridges essentially corresponding to the length of the fastening elements to be formed. Stretching the backing so that it plastically deforms results in the separation of the fastening elements.

The fastener of the present disclosure may be made from a variety of suitable materials, including thermoplastics. Examples of thermoplastic materials suitable for making the fastener using the methods described above include polyolefin homopolymers such as polyethylene and polypropylene, copolymers of ethylene, propylene and/or butylene; copolymers containing ethylene such as ethylene vinyl acetate and ethylene acrylic acid; polyesters such as poly(ethylene terephthalate), polyethylene butyrate, and polyethylene napthalate; polyamides such as poly(hexamethylene adipamide); polyurethanes; polycarbonates; poly(vinyl alcohol); ketones such as polyetheretherketone; polyphenylene sulfide; and mixtures thereof. In some embodiments, the thermoplastic useful for making the fastener comprises at least one of a polyolefin, a polyamide, or a polyester. In some embodiments, the thermoplastic useful for making the fastener is a polyolefin (e.g., polyethylene, polypropylene, polybutylene, ethylene copolymers, propylene copolymers, butylene copolymers, and copolymers and blends of these materials). In some embodiments, the fastener of the present disclosure is made from a blend of any of these thermoplastic materials and an elastomer. Examples of elastomers useful in such tie layers include elastomers such as ABA block copolymers (e.g., in which the A blocks are polystyrenic and formed predominantly of substituted (e.g., alkylated) or unsubstituted moieties and the B blocks are formed predominately from conjugated dienes (e.g., isoprene and 1,3-butadiene), which may be hydrogenated), polyurethane elastomers, polyolefin elastomers (e.g., metallocene polyolefin elastomers), olefin block copolymers, polyamide elastomers, ethylene vinyl acetate elastomers, and polyester elastomers. Examples of useful polyolefin elastomers include an ethylene propylene elastomer, an ethylene octene elastomer, an ethylene propylene diene elastomer, an ethylene propylene octene elastomer, polybutadiene, a butadiene copolymer, polybutene, or a combination thereof. Elastomers are available from a variety of commercial sources as described below. Any of these elastomers may be present in a blend with any of the thermoplastics in an amount of up to 20, 15, or 10 percent by weight.

The backing of the fastener of the present disclosure may have a variety of thicknesses. In some embodiments, including the embodiments illustrated in FIGS. 1A to 1C and FIGS. 2A to 2C, the thickness (Z4-Z5) of the backing 2 integral with the rail segments 4 and posts 6 may be up to about 300 micrometers (μall), 250 micrometers, or 200 micrometers and at least about 50 micrometers or 75 micrometers. This thickness does not include the heights of the rail segments and posts protruding from the first major surface of the backing. In some embodiments, the thickness of the thermoplastic backing is in a range from 50 to about 300 micrometers, from about 50 to about 200 micrometers, or from about 50 to about 150 micrometers.

In some embodiments, including the embodiments illustrated in FIGS. 1A to 1C and FIGS. 2A to 2C, the rows of rail segments 14 and rows of posts 16 are each independently formed on fillets 12. Referring to FIG. 1B, the fillet thickness Z6 above the backing 2 may be up to about 100 micrometers (μm), 75 micrometers, or 50 micrometers and at least about 10 micrometers or 15 micrometers. This thickness does not include the heights of the rail segments and posts protruding from the first major surface of the backing. In some embodiments, the fillet thickness Z6 is in a range from 10 to about 100 micrometers, from about 15 to about 75 micrometers, or from about 20 to about 50 micrometers. In some embodiments, the backing, excluding the rail segments, posts, and fillets, is substantially uniform in thickness. For a thermoplastic that is substantially uniform in thickness, a difference in thickness between any two points in the backing may be up 5, 2.5, or 1 percent.

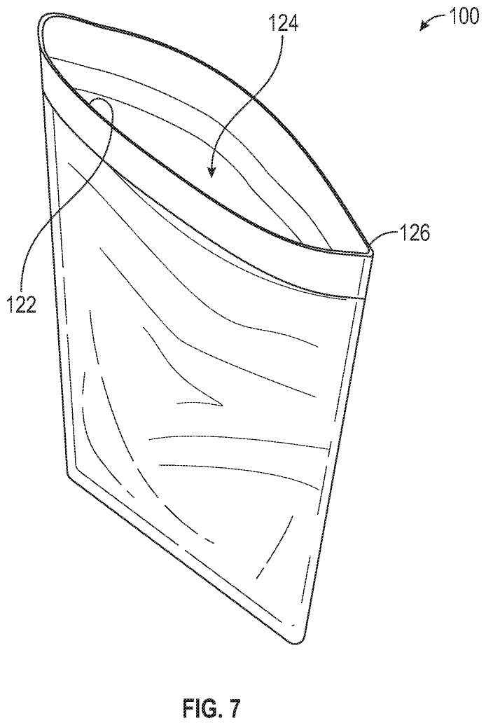

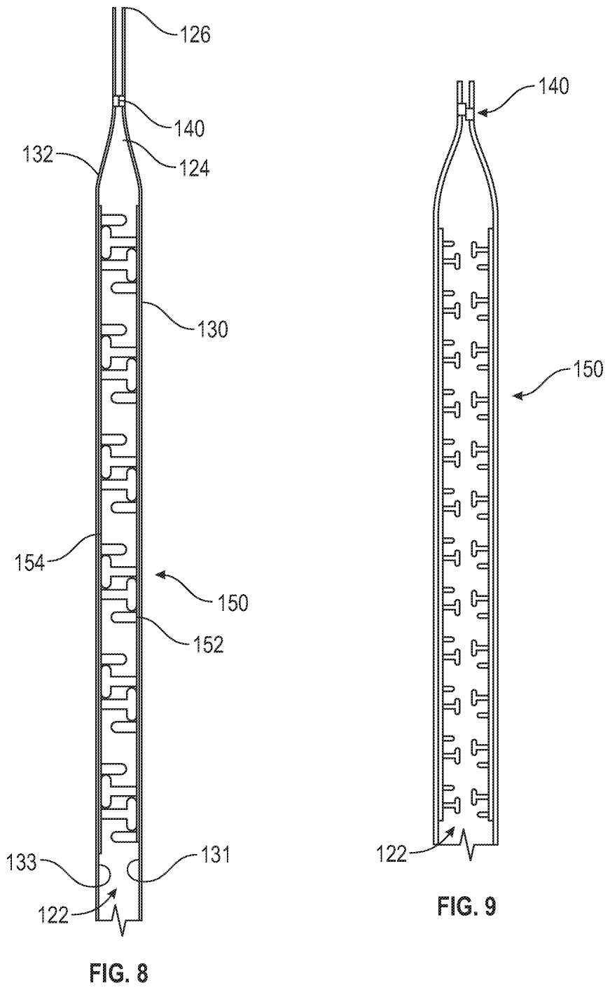

Rail segments on the first surface of the backing may have a density of at least 10 per square centimeter (cm²) (63 per square inch in²). For example, the density of the rail segments may be at least 100/cm² (635/in²), 248/cm² (1600/in²), 394/cm² (2500/in²), or 550/cm² (3500/in²). In some embodiments, the density of the rail segments may be up to 1575/cm² (10000/in²), up to about 1182/cm² (7500/in²), or up to about 787/cm² (5000/in²). Densities in a range from 10/cm² (63/in²) to 1575/cm² (10000/in²) or 100/cm² (635/in²) to 1182/cm² (7500/in²) may be useful, for example. The density of the rail segments is related to the distance between rail segments X7, measured as the center-to-center distance of the rail segments in adjacent rows as shown in FIG. 1B. A variety of distances X7 between rows of rail segments can be useful. In some embodiments, the distance X7 between rows of rail segments is 0.25 mm to 2.5 mm, 0.5 mm to 1.5 mm, or 0.6 mm to 1.2 mm. The spacing of the rows of rail segments and the posts need not be uniform, for example, as shown in FIGS. 8 to 10.

In some embodiments, the backing can be monoaxially or biaxially stretched. Stretching in the machine direction can be carried out on a continuous web of the backing, for example, by directing the web over rolls of increasing speed. Stretching in a cross-machine direction can be carried out on a continuous web using, for example, diverging rails or diverging disks. A versatile stretching method that allows for monoaxial and sequential biaxial stretching of the thermoplastic layer employs a flat film tenter apparatus. Such an apparatus grasps the thermoplastic layer using a plurality of clips, grippers, or other film edge-grasping means along opposing edges of the thermoplastic web in such a way that monoaxial and biaxial stretching in the desired direction is obtained by propelling the grasping means at varying speeds along divergent rails. Increasing clip speed in the machine direction generally results in machine-direction stretching. Stretching at angles to the machine direction and cross-direction are also possible with a flat film tenter apparatus. Monoaxial and biaxial stretching can also be accomplished, for example, by the methods and apparatus disclosed in U.S. Pat. No. 7,897,078 (Petersen et al.) and the references cited therein. Flat film tenter stretching apparatuses are commercially available, for example, from Bruckner Maschinenbau GmbH, Siegsdorf, Germany.

In some embodiments, after stretching, the backing has an average thickness of up to 150 μm, 125 μm, 100 μm, 80 μm, or 75 μm. In some embodiments, the average thickness of the backing after stretching is in a range from 30 μm to 150 μm, 50 μm to 150 μm, or 50 μm to 125 μm. In general, the backing has no through-holes before or after stretching. In some embodiments, the density of the rail segments and/or posts after stretching may be up to about 1182/cm² (7500/in²) or up to about 787/cm² (5000/in²). Densities after stretching in a range from 2/cm² (13/in²) to 1182/cm² (7500/in²), 124/cm² (800/in²) to 787/cm² (5000/in²), 248/cm² (1600/in²) to 550/cm² (3500/in²), or 248/cm² (1600/in²) to 394/cm²(2500/in²) may be useful, for example. Again, the spacing of the spacing of the rows of rail segments and the posts need not be uniform.

In some embodiments, the backing includes a multi-layer construction. The multi-layer construction can include from 2 to 10, 2 to 5, or 2 to 3 layers. The multiple layers can include films, adhesives, and tie layers. The multiple layers can be joined together using a variety of methods including coating, adhesive bonding, and extrusion lamination. In some embodiments, the backing having the protruding rail segments and posts can be made (e.g., using any of the methods described above) from a multilayer melt stream of thermoplastic materials. This can result in the protruding rail segments and posts formed at least partially from a different thermoplastic material than the one predominately forming the backing. Various configurations of upstanding posts made from a multilayer melt stream are shown in U.S. Pat. No. 6,106,922 (Cejka et al.), for example. In some embodiments, the thickness of the backing (including a multi-layer backing) combined with the height of the rail segments is up to 3300, 2000, 1000, 900, 800, 700, 650, 600, 500, 540, or 400 micrometers. In some embodiments, the thickness of the fastening system according to the present disclosure, in which the first and second fastening members are engaged with each other is up to 3300, 2000, 1000, 900, 800, 750, or 700 micrometers.

The bending stiffness of the fastener (e.g., at an axis parallel to the width of the fastener) is influenced by the modulus of the material or materials making up the backing, the thickness of the layer or layers making up the backing, the distance between the structures (including rail segments and posts) on the backing, and the dimension of the fastener in a parallel to the bending axis. In general, materials, thicknesses of the layer or layers in the fastener, and distances between structures can be selected to provide the fastener with a desirable bending stiffness. Advantageously, in many embodiments of the fastener of the present disclosure, the bending stiffness of the fastener is low enough such that the fastener does not unintentionally open when the fastener is bent. In some of these embodiments, the bending stiffness of the fastener in a closed configuration is in a range from 100 mN/mm to 1500 mN/mm, 200 mN/mm to 1200 mN/mm, or 300 mN/mm to 1000 mN/mm as measured by a Flexural Stiffness Test Method, for example, as described in the Examples, below.

In some embodiments, the fastener of the present disclosure and/or the backing of the fastener includes a tie layer. Tie layers can include elastomeric materials or other materials that have lower melting points than the backing integral with the rail segments and posts. Examples of elastomers useful in such tie layers include elastomers such as ABA block copolymers (e.g., in which the A blocks are polystyrenic and formed predominantly of substituted (e.g., alkylated) or unsubstituted moieties and the B blocks are formed predominately from conjugated dienes (e.g., isoprene and 1,3-butadiene), which may be hydrogenated), polyurethane elastomers, polyolefin elastomers (e.g., metallocene polyolefin elastomers), olefin block copolymers, polyamide elastomers, ethylene vinyl acetate elastomers, and polyester elastomers. Examples of useful polyolefin elastomers include an ethylene propylene elastomer, an ethylene octene elastomer, an ethylene propylene diene elastomer, an ethylene propylene octene elastomer, polybutadiene, a butadiene copolymer, polybutene, or a combination thereof. Various elastomeric polymers and other polymers may be blended to have varying degrees of elastomeric properties. For example, any of these elastomeric materials may be present in a range from 50% by weight to 95% by weight in a blend with any of the thermoplastics described above for forming the backing integral with the rail segments and posts.

Many types of elastomers are commercially available, including those from BASF, Florham Park, N.J., under the trade designation “STYROFLEX”, from Kraton Polymers, Houston, Tex., under the trade designation “KRATON”, from Dow Chemical, Midland, Mich., under the trade designation “PELLETHANE”, “INFUSE”, VERSIFY″, “NORDEL”, and “ENGAGE”, from DSM, Heerlen, Netherlands, under the trade designation “ARNITEL”, from E. I. duPont de Nemours and Company, Wilmington, Del., under the trade designation “HYTREL”, from ExxonMobil, Irving, Tex. under the trade designation “VISTAMAXX”, and more.

In some embodiments, the fastener of the present disclosure and/or the backing of the fastener includes a layer of a hot melt adhesive. Hot melt adhesives are typically non-tacky at room temperature, and use of hot melts can decrease contamination on equipment during the handling of the film and lamination. Suitable hot melt adhesives include those based on ethylene-vinyl acetate copolymers, ethylene-acrylate copolymers, polyolefins, polyamides, polyesters, polyurethanes, styrene block copolymers, polycaprolactone, and polycarbonates and may include a variety of tackifying resins, plasticizers, pigments, fillers, and stabilizers. Examples of suitable hot melt adhesives include those available from 3M Company, St. Paul, Minn., under the trade designation “3M SCOTCH-WELD” hot melt adhesives (e.g., products 3731 B and 3764 PG).

In some embodiments, the tie layer or hot melt adhesive will be thermally activated in a temperature range of 90° C. to 125° C. depending on time and pressure and can be useful for making a secure bond to a substrate, such as a film used in a reclosable package. Referring again to FIG. 1B, the tie layer or hot melt adhesive layer 3 can have any useful thickness Z5. In some embodiments, the tie layer or hot melt adhesive layer 3 has a thickness Z5 of up to 0.1 mm, 0.075 mm, 0.05 mm, or 0.025 mm. Typically, the tie layer or hot melt adhesive layer 3 has a thickness of at least 0.005 mm or 0.01 mm. Useful thicknesses Z5 include those in a range from 0.005 mm to 0.1 mm, 0.005 mm to 0.05 mm, and 0.01 mm to 0.025 mm.

The fastener of the present disclosure can be useful for joining two articles together for a variety of purposes. For example, the fastener of the present disclosure can be useful as a self-mating fastener for a reclosable package. The self-mating fastener can be connected to a package or pouch. The self-mating fastener can include an open configuration and a closed configuration. When in the open configuration, the self-mating fastener is adapted to allow access to an interior volume of the pouch through an opening disposed in the pouch after a first opening of the pouch. Further, when in the closed configuration, the self-mating fastener is adapted to prevent access to the interior volume of the pouch through the opening.

Reclosable Packages

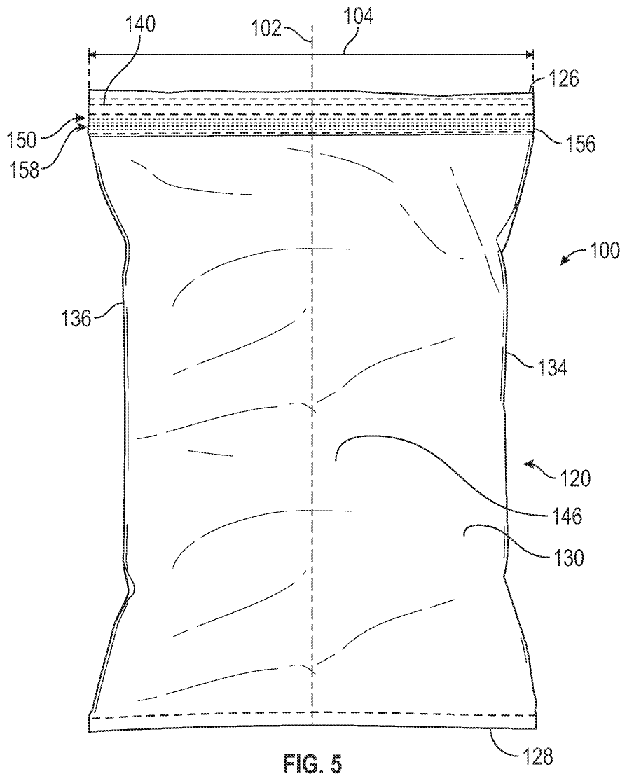

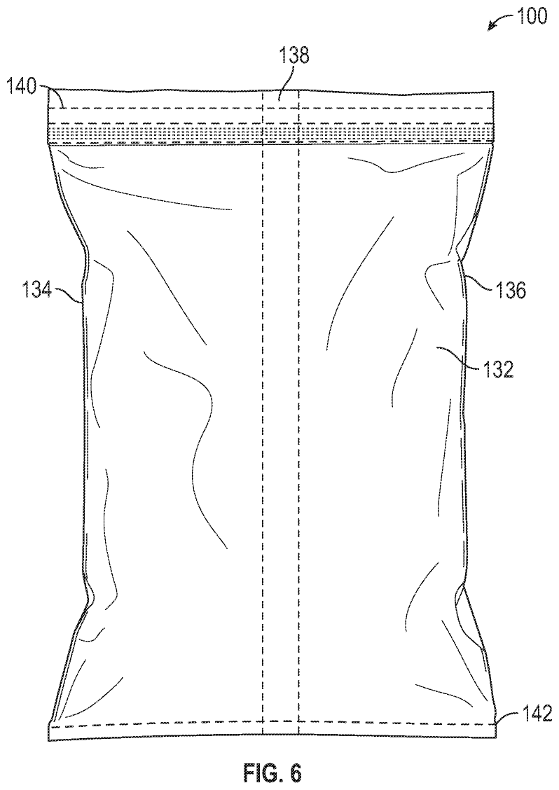

FIGS. 5-10 are various views of one embodiment of a reclosable package 100. The reclosable package 100 includes a pouch 120 that defines an interior volume 122 and an opening 124 that provides access to the interior volume. The pouch 120 also includes an upper seal region 140 disposed adjacent the opening 124 that is adapted to be broken to allow a first opening of the pouch. The reclosable package 100 also includes a self-mating fastener 150 connected to the pouch 120. The self-mating fastener 150 can include any suitable fastener, e.g., fastener 1 of FIGS. 1A-C. The self-mating fastener 150 includes an open configuration (as shown in FIG. 7) and a closed configuration (as shown in FIGS. 5-6). When in the open configuration, the self-mating fastener 150 is adapted to allow access to the interior volume 122 of the pouch 120 through the opening 124 after the seal region 140 has been broken. Further, when in the closed configuration, the self-mating fastener 150 is adapted to prevent access to the interior volume 122 of the pouch 120 through the opening 124.

As used herein, the term “allow access” means that a user of the reclosable package 100 can reach into the interior volume 122 of the pouch 120 through the opening 124 and grasp at least a portion of consumer goods disposed within the interior volume. Further, as used herein, the term “prevent access” means that the user of the reclosable package cannot reach into the interior volume 122 of the pouch 120 through the opening 124 to grasp at least a portion of the consumer goods disposed within the interior volume without first manipulating the self-mating fastener 150.

The pouch 120 can include any suitable bag or package that defines the interior volume 122. Further, the pouch 120 can be adapted to contain any suitable items. In one or more embodiments, the pouch 120 can be adapted to contain any suitable consumer goods, e.g., foodstuffs such as crackers, potato chips, and cheese, bulk granular or powdered products, animal feed, lawn and garden products, etc.

The pouch 120 can be formed using any suitable technique or techniques. In the embodiments illustrated in FIGS. 5-10, the pouch 120 is formed from a single piece of material or film that is connected along a rear seal region 138 that extends in a vertical direction that is substantially parallel to first and second side edges 134, 136 of the pouch as shown in FIG. 6. Further, the pouch 120 includes the upper seal region 140 and a lower seal region 142. The rear, upper, and lower seal regions 138, 140, 142 can be formed using any suitable technique or techniques, e.g., ultrasonic welding, adhering (e.g., using a hot melt adhesive as described herein), heat sealing, and combinations thereof. In one or more embodiments, the seal regions 138, 140, 142 can be formed using the same technique or techniques. In one or more embodiments, one or more of the seal regions 138, 140, 142 can be formed using a technique that is different from the technique utilized to form the other seal regions.

The pouch 120 can have any suitable dimensions and take any suitable shape or combination of shapes. Further, the pouch 120 includes a front panel 130 and a back panel 132. The front panel 130 and the back panel 132 can meet at the first and second side edges 134, 136. In one or more embodiments, the front panel 130 and the back panel 132 are integral such that the pouch 120 does not include seams or seal regions adjacent one or both of the first and second side edges 134, 136. As used herein, the term “adjacent the side edge” means that an element or component of the package 100 is disposed closer to one of the first and second side edges 134, 136 than to the rear seal region 138. In one or more embodiments, the front and back panels 130, 132 can be connected to each other at side edges 134, 136 using any suitable technique or techniques. For example, in one or more embodiments, the front panel 130 and the back panel 132 can be made separately and then joined together at the first and second side edges 134, 136 by connecting the front panel to the back panel.

The pouch 120 can include the opening 124 (FIG. 7) that provides access to the interior volume 122. The opening 124 can be disposed in any suitable location on the pouch 120. As shown in FIG. 7, the opening 124 is disposed adjacent a top edge 126 of the pouch 120. As used herein, the term “adjacent the top edge” means that an element or component of the package 100 is disposed closer to the top edge 126 of the pouch 120 than to a bottom edge 128 of the pouch. The opening 124 can take any suitable shape and have any suitable dimensions. In one or more embodiments, the opening extends between first and second side edges 134, 136 of the pouch. In one or more embodiments, one or more seal regions may be disposed between edges of the opening 124 and the first and second side edges 134, 136 of the pouch 120 such the opening does not extend to one or both of the first and second side edges of the pouch. In one or more embodiments, the opening 124 of the pouch 120 can be defined by the top edge 126 of the pouch.

In one or more embodiments, the pouch 120 can include a seal region disposed adjacent the opening 124 that is adapted to be broken to allow a first opening of the pouch such that the user can access consumer goods disposed within the interior volume 122. As used herein, the term “first opening” refers to the first time that the reclosable package is opened by the user following manufacturing and filling of the package. In the embodiments illustrated in FIGS. 5-10, such seal region includes the upper seal region 140. The upper seal region 140 seals the pouch 120 prior to the first opening of the pouch to preserve the consumer goods disposed within the interior volume 122. To access such consumer goods, the user can break the upper seal region 140 using any suitable technique or techniques, e.g., pulling apart, tearing, cutting, etc.

The pouch 120 can be made using any suitable material or materials, e.g., one or more inorganic, polymeric, and metallic materials. In one or more embodiments, the pouch 120 can include one or more polymeric materials such as a polyolefin (e.g., oriented polypropylene OPP, low density polyethylene (LDPE), and linear low polyethylene (LLDPE)), a polyester (e.g., poly(ethylene terephthalate) (PET)), a polyacrylate, and ethylene vinyl alcohol (EVOH). Films of these materials are available as single-layer films, for example, and as multiple layer films including functional tie layers. Multiple layer films can be made by coextrusion or stepwise extrusion. The functional tie layer can be made of any of the polymeric materials described for the pouch blended with 5% by weight to 50% by weight of a functional polymer. The multiple layer film is usually configured with the tie layer on the inside of the pouch 120 and can allow for adhesive bonding and hermetic sealing of the pouch. Many functional polymers useful as tie layer resins are commercially available, for example, from Dow Chemical Company under the trade designation “AMPLIFY”. In one or more embodiments, the pouch 120 can include a flexible material. Tie layers on the pouch may also include any of the elastomeric materials described above in connection with the tie layer on the fastener.

The pouch 120 can include any suitable graphic or graphics (not shown) disposed on one or both of the front and back panels 130, 132 using any suitable technique or techniques, e.g., ink jet printing, laminating, digital printing, flexographic printing, screen printing, ink transfer, and combinations of these. In one or more embodiments, the graphic (not shown) can be disposed on the front panel of the pouch, where a portion of the graphic is disposed over the self-mating fastener 150 when the fastener is in the closed configuration.

Connected to the pouch 120 is the self-mating fastener 150 of the present disclosure as described above in any of its embodiments. The self-mating fastener 150 can be connected to the pouch 120 in any suitable location. In the embodiment illustrated in FIGS. 5-10, the self-mating fastener 150 is connected to the pouch 120 adjacent the top edge 126 of the pouch. In one or more embodiments, the self-mating fastener 150 is disposed at the top edge 126 of the pouch 120. Further, in one or more embodiments, the self-mating fastener 150 can be disposed adjacent a center region 146 of the pouch 120. As used herein, the term “adjacent the center region” means that the self-mating fastener 150 is disposed closer to the center region 146 of the pouch 120 than to the top edge 126 or the bottom edge 128 of the pouch.

Further, the self-mating fastener 150 of the present disclosure can be disposed in any suitable location relative to the opening 124 of the pouch 120 such that the fastener when in the open configuration can allow access to the interior volume 122 of the pouch through the opening, after the upper seal region 140 has been broken and that when in the closed configuration the fastener is adapted to prevent access to the interior volume of the pouch through the opening.

For example, as shown in FIG. 7, the self-mating fastener 150 is disposed adjacent the opening 124. As used herein, the term “adjacent the opening” means that the self-mating fastener 150 is disposed such that the fastener can manipulate the opening such that is sufficiently open to allow access to the consumer goods disposed within the pouch 120 and sufficiently closed to prevent access to the consumer goods. In one or more embodiments, the self-mating fastener 150 can be disposed within the opening 124. In one or more embodiments, the self-mating fastener 150 can be disposed outside of the opening 124 along an edge of the opening such that the fastener can be manipulated between the open and closed configurations to open and close the opening as is further described herein.

The self-mating fastener 150 can have any suitable dimensions and take any suitable shape or shapes. In one or more embodiments, the self-mating fastener 150 can be connected to the pouch 120 adjacent the top edge 126 of the pouch and extend between the first and second side edges 134, 136 of the pouch as shown in FIGS. 5-6. The self-mating fastener 150 can extend to one or both of the first and second side edges 134, 136 of the pouch. In one or more embodiments, the self-mating fastener 150 can be adapted such that one or both of a first side edge 156 and a second side edge 158 of the fastener is spaced apart from the respective first and second side edges 134, 136 of the pouch 120 any suitable distance. In such embodiments, the pouch 120 may also include one or more seal regions disposed between one or both of the first and second side edges 156, 158 of the self-mating fastener 150 and the first and second side edges 134, 136 of the pouch 120 such that the fastener along with the seal regions seal the pouch along a width of the pouch.

As shown in FIG. 8, which is a schematic cross-section view of a portion of the pouch 120 of FIGS. 5-7, the self-mating fastener 150 includes a first fastener member 152 and a second fastener member 154. The first fastener member 152 can be the same as the second fastener member 154 or different from the second fastener member. Further, the first and second fastener members 152, 154 can be connected to the pouch 120 in any suitable location. In the embodiment illustrated in FIG. 8, the first fastener member 152 is disposed on an inner surface 131 of the front panel 130 and the second fastener member 154 is disposed on an inner surface 133 of the back panel 132. In one or more embodiments, the first fastener member 152 can be disposed on the inner surface 131 of the front panel 130 adjacent the top edge 126 of the pouch 120, and the second fastener member 154 can be disposed on the inner surface 133 of the back panel 132 adjacent the top edge of the pouch.

In one or more embodiments, the first fastener member 152 can overlap with the second fastener member 154 in a direction orthogonal to the front and back panels 130, 132 such that at least a portion of the first fastener member can mate with the second fastener member. In one or more embodiments, the first fastener member 152 is registered with the second fastener member 154 in the direction orthogonal to the front and back panels 130, 132 as shown, e.g., in FIG. 8.

The self-mating fastener 150 can be connected to the pouch 120 using any suitable technique or techniques. In one or more embodiments, the fastener 150 is adhered to the pouch 120 using any suitable adhesive or combination of adhesives, including any of the hot melt adhesives described herein. Further, in one or more embodiments, self-mating fastener 150 can be ultrasonically bonded to the pouch 120. In one or more embodiments, the fastener 150 can be mechanically attached to the pouch 120 using any suitable technique or techniques. In one or more embodiments, a tie layer as described herein in any of its embodiments may be disposed between one or both of the first and second fastener members 152, 154 and the front and back panels 130, 132 respectively.

When tie layers or hot melt adhesives are used to connect the self-mating fastener 150 of the present disclosure to the pouch 120, heating the adhesive or tie layer can be carried out using high-temperature impingement fluid as described in U.S. Pat. No. 9,096,960 (Biegler et al.), U.S. Pat. No. 9,126,224 (Biegler et al.), and U.S. Pat. No. 8,956,496 (Biegler et al.). In some embodiments, the high-temperature fluid is a high-temperature gas (e.g., air, dehumidified air, nitrogen, an inert gas, a mixture of any of these, or another gas mixture). In some embodiments, the high-temperature fluid is high-temperature air. The high-temperature fluid can be directed toward the tie layer or hot melt adhesive only, or the high-temperature fluid can be directed toward both the tie layer or hot melt adhesive and the film useful for forming the pouch. In some embodiments, high-temperature air is directed toward the tie layer or hot melt adhesive only before it is bonded to the pouch. In some embodiments, connecting the self-mating fastener 150 to the pouch 120 includes impinging high-temperature fluid, including any of those described above, onto a second surface of a web of the self-mating fastener while it is moving, wherein the second surface is the surface opposite the first surface bearing the rail segments and posts. In some of these embodiments, the second surface of the web includes a tie layer. In some embodiments, the second surface of the web includes a hot melt adhesive. Optionally, either sequentially or simultaneously, connecting the self-mating fastener 150 to the pouch 120 includes impinging high-temperature fluid, including any of those described above, onto a surface of a web of a film useful for forming the pouch while the web of the film is moving. Connecting the self-mating fastener 150 to the film can then be carried out by contacting the second surface of the web of the self-mating fastener to the web of the film useful for forming the pouch. A heated bar may also be useful for connecting the self-mating fastener to the pouch. The self-mating fastener, tie layer, and/or hot melt adhesive may be contacted with a heated bar one or multiple times to ensure a good bond to the packaging film. Typically, the heated bar is contacted to the non-adhesive-containing side of the packaging film.

As mentioned herein, the self-mating fastener 150 has an open configuration and a closed configuration. For example, as shown in FIG. 8, the self-mating fastener 150 is in the closed configuration such that the user is prevented from accessing the interior volume 122 of the pouch 120 through the opening 124 of the pouch. Further, as shown in FIG. 8, the upper seal region 140 is intact and has not yet been broken upon a first opening of the pouch 120. As a result, the consumer goods disposed within the interior volume 122 of the pouch 120 can be preserved by the seal region 140.

In general, the self-mating fastener 150 can be connected to the pouch 120 such that the fastener is in this closed configuration when the bag is manufactured. In one or more embodiments, self-mating fastener 150 can be connected to the pouch 120 during manufacturing such that it is in an open configuration. For example, FIG. 9 is a schematic cross-section view of a portion of the pouch 120 of FIGS. 5-7. As shown in FIG. 9, the self-mating fastener 150 is in the open configuration. As used herein, the term “open configuration” means that one or more portions of the self-mating fastener 150 has been separated such that the user may reach into the pouch 120 through the opening 124 and the self-mating fastener to grasp a portion of the consumer goods disposed within the interior volume 122 of the pouch.

As also shown in FIG. 9, the upper seal region 140 is still intact and has not yet been broken upon the first opening of the pouch 120. In embodiments where the self-mating fastener 150 is connected to the pouch 120 such that it is in the open configuration prior to the first opening of the pouch 120, the user may grasp portions of the front and back panels 130,132 and manipulate the panels in a direction away from each other. During this manipulation by the user, the upper seal region 140 may remain intact while portions of the self-mating fastener 50 may be separated such that it is in the open configuration as shown in FIG. 9. In one or more embodiments, manipulation by the user upon the first opening of the pouch 120 may instead first separate the upper seal region 140 such that the seal region is at least partially broken prior to manipulation of the self-mating fastener 150 from the closed configuration to the open configuration.

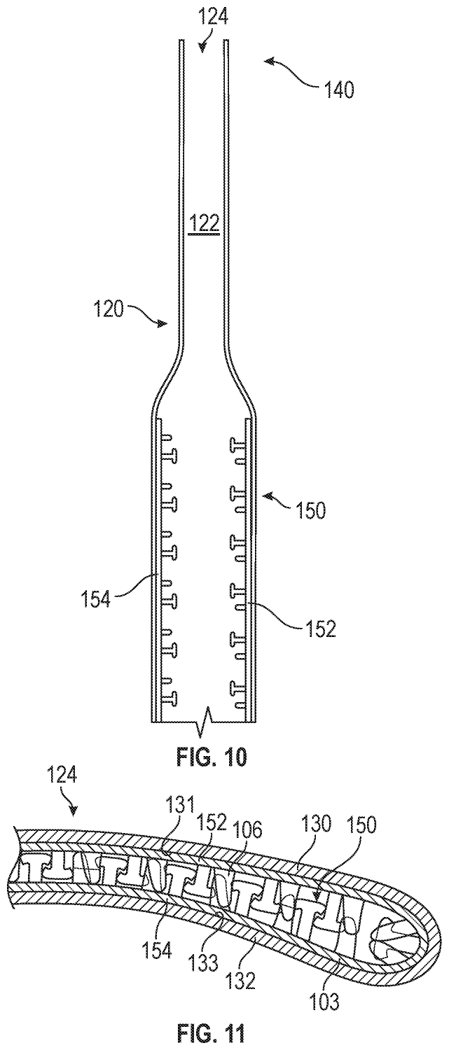

FIG. 10 is a schematic cross-section view of the pouch 120 of FIG. 5-7, where the upper seal region 140 has been broken upon the first opening of the pouch and the self-mating fastener 150 is in the open configuration. As shown in FIG. 10, the user may now access the interior volume 122 of the pouch 120 through the opening 124 and through the self-mating fastener 150. The user may then manipulate the self-mating closure 150 from the open configuration to the closed configuration such that the user can no longer access the interior volume 122 of the pouch 120.

FIG. 11 is a schematic cross-section view of an embodiment of the opening 124 of pouch 120 of FIG. 5-7, where the self-mating fastener 150 is in the closed configuration. The self-mating fastener 150 includes a first fastener member 152 and a second fastener member 154. In the illustrated embodiment, the first fastener member 152 and the second fastener member 154 are part of the same strip of material, folded over onto itself. The self-mating fastener 150 is folded, for example, along an axis parallel to the width (W) of the fastener, referring to FIG. 1A, so that a row of posts 106 is visible in the cross-section view. In the embodiment illustrated in FIG. 11, the first fastener member 152 is disposed on an inner surface 131 of the front panel 130 and the second fastener member 154 is disposed on an inner surface 133 of the back panel 132 of the pouch. The first fastener member 152 is attached to inner surface 131 of the front panel 130 and the second fastener member 154 is attached to inner surface 133 of the back panel 132 using tie layer 103. Advantageously, the thickness of the self-mating fastener 150 in this folded configuration can be up to 1000, 900, 800, 700, 600, 500, 450, or 400 micrometers. Such a thickness can allow the self-mating fastener 150 to be connected to the pouch 120 is in this folded configuration when the bag is manufactured.

Any suitable technique or techniques may be utilized by the user to manipulate the self-mating fastener 150 to the closed configuration. For example, the user may press the self-mating closure 150 together by placing one hand on the front panel 130 and another hand on the back panel 132 and pressing the first fastener element 152 against the second fastener element 154. Further, for example, the user may place the package 100 on a flat surface such that either the first or second panels 130, 132 are in contact with the surface, and then press the first and second fastener elements 152, 154 together.

When in the closed configuration as shown in FIG. 8, the self-mating fastener 150 may prevent consumer goods disposed within the interior volume 122 of the pouch 120 from falling or spilling out of the pouch through the opening 124. Further, in one or more embodiments, the self-mating fastener 150 may seal the pouch 120 in the closed configuration such that the consumer goods disposed within the interior volume 122 remain fresh.

Any suitable technique or techniques can be utilized to determine whether the self-mating fastener 150 is in the closed configuration. For example, in one or more embodiments, the self-mating faster 150 is considered to be in the closed configuration when a force to open the self-mating fastener is at least about 0.1 Newtons and no greater than 1.0 Newtons as determined from the mean maximum load from the T-Peel Test Method described in the Examples. In some embodiments, the force to open the self-mating fastener is in a range 0.2 N to 0.9 N or 0.3 N to 0.8 N as determined from the mean maximum load from the T-Peel Test Method described in the Examples.

Further, in one or more embodiments, the force required to achieve a closed configuration from an open configuration, as previously defined, is no more than 0.1 Newtons (N) but at least 0.01 N as determined utilizing the Force to Close Test Method described in the Examples. In one or more embodiments, the force required to achieve a closed configuration from an open configuration is no more than 0.01 N/mm but at least 0.001 N/mm as determined utilizing the Force to Close Test Method. In some embodiments, the force required to achieve a closed configuration from an open configuration is in a range from 0.015 N to 0.09 N or 0.02 N to 0.08 N as determined utilizing the Force to Close Test Method. In some embodiments, transition from an open configuration to a closed configuration is readily achieved with finger pressure.

The self-mating fastener 150 and the material utilized for the pouch 120 can be selected to provide any desirable stiffness in resistance to bending about a pouch axis 102 that is perpendicular to a length 104 of the self-mating fastener as shown in FIG. 5. Any suitable technique or techniques can be utilized to determine the stiffness in resistance to bending of the pouch 120 and the self-mating fastener 150. The self-mating fastener 150 can have a flexural rigidity of at least about 100 mN/mm and up to about 1500 mN/mm as determined utilizing the Flexural Stiffness Test Method described in the Examples. In some embodiments, the bending stiffness of the fastener is in a range from 100 mN/mm to 1500 mN/mm, 200 mN/mm to 1200 mN/mm, or 300 mN/mm to 1000 mN/mm as measured by the Flexural Stiffness Test Method. With a bending stiffness in these ranges, typically and advantageously, the fastener does not unintentionally open when the fastener is bent.

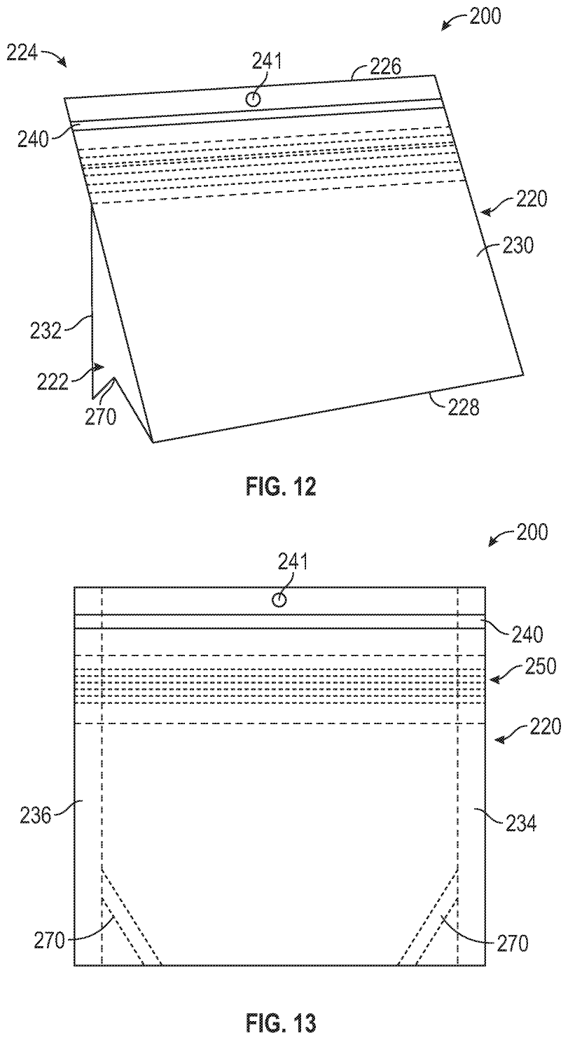

The various embodiments of a reclosable package described herein can include any suitable configuration of pouch. For example, FIGS. 12-13 are various views of another embodiment of a reclosable package 200. All of the design considerations and possibilities regarding the package 100 of FIGS. 5-11 apply equally to the package 200 of FIGS. 12-13. The reclosable package 200 includes a pouch 220 that defines an interior volume 222 and an opening 224 that provides access to the interior volume. In the embodiment illustrated in FIGS. 12-13, the opening is disposed adjacent a top edge 226 of the pouch 220. The pouch 220 also includes an upper seal region 240 disposed adjacent the opening 224 that is adapted to be broken to allow a first opening of the pouch.

The pouch 220 further includes a front panel 230 and a back panel 232. The pouch 220 can be formed utilizing a single film that can be sealed along a first side seal region 234 and a second side seal region 236. In one or more embodiments, the pouch 220 also includes the upper seal region 240. Further, an opening 241 can be disposed adjacent the upper seal region 240 such that the pouch 220 can be hung on a display rack.

The package 200 also includes a self-mating fastener 250 according to the present disclosure connected to the pouch 220. The self-mating fastener 250 can be connected to the pouch 220 in any suitable location. In one or more embodiments, the self-mating fastener 250 is disposed adjacent the opening 224 of the pouch 220.

The pouch 220 can also include a bottom gusset 270 disposed adjacent a bottom edge 228 of the pouch. The bottom gusset 270 can be folded inwardly from the bottom edge 228 of the pouch. The bottom gusset 270 can be formed utilizing any suitable technique or techniques.

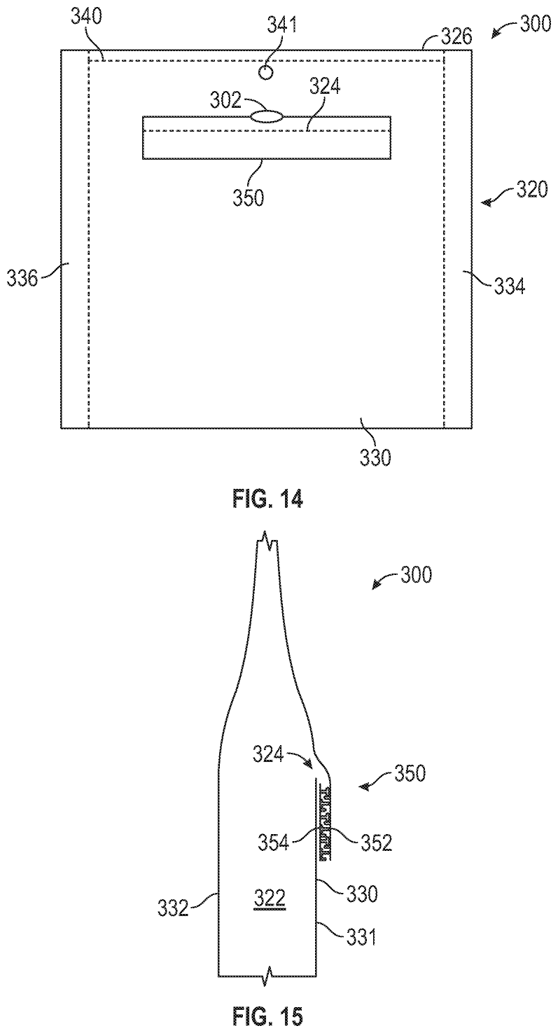

Further, FIGS. 14-15 are various views of another embodiment of a reclosable package 300. All of the design considerations and possibilities regarding the reclosable package 100 of FIGS. 5-11 apply equally to the package 300 of FIGS. 14-15. The reclosable package 300 includes a pouch 320 having a front panel 330 and a rear panel 332 that can be joined together at a first side seal region 334 and a second side seal region 336. The front and back panels 330, 332 can also be joined together at an upper seal region 340 adjacent a top edge 326 of the pouch. An opening 341 can be disposed adjacent the top edge 326 such that the package 300 can be hung on a display rack. The reclosable package 300 also includes a self-mating fastener 350 of the present disclosure.

The front panel 330 includes a perforated opening 324 that is adapted to allow a user to separate the perforation and access consumer goods disposed within an inner volume 322 of the pouch 320. In one or more embodiments, the pouch 320 can also include a tear strip (not shown) disposed over the self-mating fastener 350 that is adapted to allow the user to remove the strip and access the interior volume 322 of the pouch.

The self-mating fastener 350 can be disposed adjacent opening 324 on an outer surface 331 of the front panel 330. In one or more embodiments, portions of the self-mating fastener 350 can extend over the opening. For example, a first fastener element 352 of the self-mating fastener 350 can cover the opening 324 while a second fastener element 354 of the fastener includes a first portion disposed on a portion of the outer surface 331 of the front panel 330 above the opening when the pouch 320 is positioned in a vertical orientation (i.e., a pouch axis that extends parallel to the first and second side seal regions 334, 336 is substantially parallel to a normal to the Earth's surface), and a second portion of the second fastener element is disposed below the opening. A recess 302 can be formed in the self-mating fastener 350 to allow a user to grasp the first fastener element 352 and pull the first fastener element in a direction away from the second fastener element 354 to manipulate the self-mating fastener from a closed configuration to an open configuration.

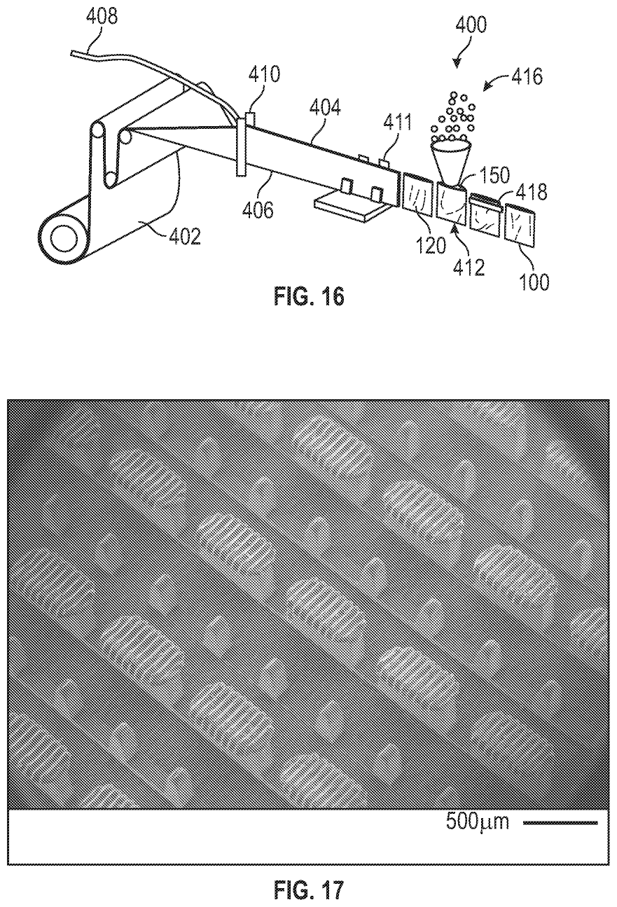

The various embodiments of reclosable packages described herein can be manufactured using any suitable technique or techniques. For example, FIG. 16 is a schematic perspective view of one embodiment of an apparatus 400 and method for forming the reclosable package 100 of FIGS. 5-11. Although described in reference to reclosable package 100 of FIGS. 5-11, the apparatus 400 can be utilized to form any suitable reclosable package. A film 402 is provided either in roll or sheet form and conveyed to station 410, where closure material 408 is connected to the film using any suitable technique or techniques. The film can include a top edge 404 and a bottom edge 406. The closure material 408 can be disposed in any suitable location on the film 402, e.g., adjacent the top edge 404.

The closure material 408 can include any suitable closure material. In one or more embodiments, the closure material 408 includes the first fastener element 152 mated with the second fastener element 154. In one or more embodiments, the closure material 408 can include either the first fastener element 152 or the second fastener element 154. In one or more embodiments, the same closure material can be utilized to form both the first fastener element 152 and the second fastener element 154. In such embodiments, the first fastener element 152 can be disposed on a first region of the film 402, and the second fastener element 154 can be disposed on a second region of the film such the first and second fastener elements 152, 154 are aligned when the pouch 120 is formed from the film.

At station 411, the film 402 can be slit or cut to form several individual sheets that are utilized to form individual pouches 120. Further, the lower seal region 142 can be formed at the bottom edge 128 of the pouch 120 at station 411 prior to disposal of consumer goods 416 within the interior volume 122 of the pouch at station 412. After the pouch 120 is filled, the upper seal region 140 can be formed at the top edge 126 of the pouch at station 418 such that the consumer goods 416 are sealed within the package 100. Any suitable technique or techniques can be utilized to form the upper and lower seal regions 140, 142.

While reclosable packages with fasteners have been reported, the fasteners can be stiff and bulky, making these packages difficult to manufacture and fill with consumer goods. Furthermore, fasteners than utilize hooks and loops can collect particles from the stored consumer goods or the environment outside of the package that contaminate the fastener. Such contamination can prevent the fastener from being completely closed, thereby allowing portions of the consumer goods to spill out of the package or prevent the package from preserving the freshness of the consumer goods.

In addition to the advantages of the fastener of the present discourse described above, various embodiments of the fastener of the present disclosure can provide one or more advantages over other fasteners currently-available for reclosable packages. For example, one or more embodiments of the fastener can have a reduced thickness compared to currently-available fasteners such that the fastener can be connected to a packaging film used to form the package without compromising roll stability while also minimizing roll loss. As described above, in some embodiments, the thickness of the fastening system according to the present disclosure, in which the first and second fastening members are engaged with each other is up to 1000, 900, 800, 700, 600, 500, 450, or 400 micrometers. Also, as described above, in some embodiments, the fastener includes a tie layer or hot melt adhesive that can be thermally activated at relatively low temperature (e.g., 90 to 125° C.). In some embodiments, at least one of the thickness of the fastening system or the low-temperature activation of the tie layer can provide aesthetic advantages when the fastener is attached to a package. For example, any graphics on the package may have little or no distortion in the location of the fastener. Further, the fastener of the present disclosure can be more flexible than currently-available fasteners such that the fastener does not unintentionally open if the fastener is bent, thereby preventing consumer goods disposed within the pouch from spilling out of the pouch. Further, one or more embodiments of the fastener of the present disclosure can be more contamination-resistant by preventing food debris such as small particles and salt from contaminating the fastener.

Electronic Component Fastening System

Fastening systems as described above may also be deployed in fastening applications demanding reworkability and thinness. One such application is the securing of components, such as electronic batteries, logic boards, chassis components, flexible printed circuits, display modules, optical cameras, infrared devices, dot projectors, antennas, speakers, proximity sensors, wireless charging modules, printed circuit boards, electrical insulation, thermal insulation, electromagnetic shielding materials, keyboard components, taptic engines, magnetic fastening elements, wire wraps, and external fastening elements such as watch band straps or detachable keyboards, mice, or touch sensitive pads in or to electronic devices, such as smart phones, tablets, or computers. Most components bonded to the chassis of an electronic device are fastened using screws, adhesives, or lengths of double-sided adhesive tape. In the case of tapes, the tape is typically relatively thick, in some cases having a backing of foam, with adhesives coating each major side. Some of the tapes are, to some degree, stretch releasable. However, removal of a components secured by tapes is cumbersome, and the tape is not amenable to reworkability, meaning that once the component is placed in the chassis, removing it is tricky and requires the destruction of the double-sided tape. This can result in increased costs (both for labor and for when additional tape is required for the re-placement of a component in a chassis), and can complicate component replacement and end-of-life recycling initiatives for electronic devices, which require that batteries be removed from the device. Adhesives present many of the same complications—low reworkability, for example, but additionally present unique complexities associated with storage and application. Screws may be difficult to apply in some applications.

In contrast, fastening systems as described herein may securely hold a battery or other component in place within the chassis of an electronic device, and allow an operator to dislodge the battery or other component entirely upon the application of an intentional force, as through the use of a small prying tool or otherwise. In contrast to a single use foam tape, which is destroyed upon removal, fastening systems as described herein may be re-fastened, allowing for example a component to be removed and then re-installed in an electronic device. In a manufacturing environment, this allows for easy and clean disassembly of components, if necessary, without the waste and difficulty of using double-sided adhesive tapes.

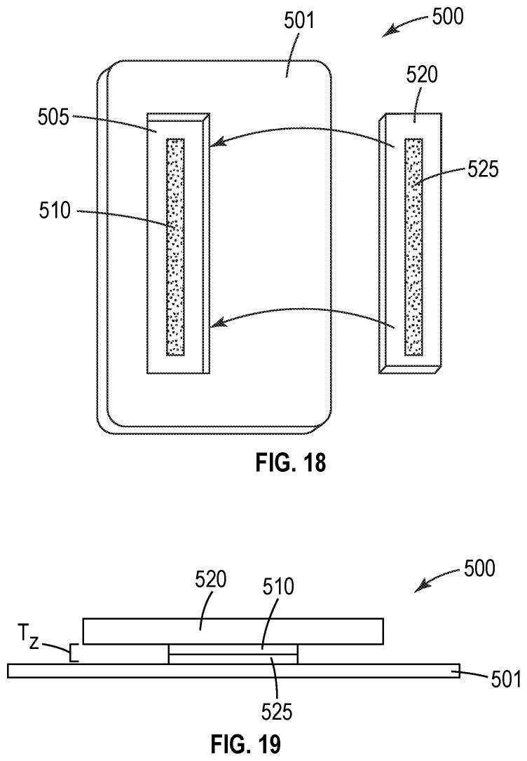

FIG. 18 is a drawing of an electronic device 500, in this case a smart phone. The front side of the device, that is, the display and lens, has been removed, revealing chassis 501 and battery compartment 505. Battery 520 is shown external to the device. The battery 520 is one exemplary component within electronic device 500, which may be amenable to fastening with fastening systems disclosed herein. Other components such as electronic batteries, logic boards, chassis components, flexible printed circuits, display modules, optical cameras, infrared devices, dot projectors, antennas, speakers, proximity sensors, wireless charging modules, printed circuit boards, electrical insulation, thermal insulation, electromagnetic shielding materials, keyboard components, taptic engines, magnetic fastening elements, wire wraps, and external fastening elements such as watch band straps or detachable keyboards, mice, or touch sensitive pads could be attached in a similar fashion. Within compartment 505, a length of self-mating fastener 510 according to the present disclosure has been applied to chassis 501. This application may be by machine or by hand. Fastener 510 is adhesive-backed, and readily sticks to chassis 501. Battery 520 also includes a length of self-mating fastener 525, which is the same pattern as fastener 510, and may be cut from the same roll. Battery 520 is flipped over, electronically coupled to various electronic components of the electronic device 500, then inserted into compartment 505, aligning the length of fastener 510 and the length of fastener 525. The battery is secured by applying a uniform pressure to the back of the battery, causing the fastener elements of the two opposed lengths to interlock. Removal of the battery may be accomplished, in some embodiments, by introducing an upward force (as by prying) to the lower major side of the battery, causing the two fastener elements to cleanly dislodge from one another.

To be well suited for use in an electronic device component bonding scenarios, particularly where the device is handheld (for example, a smart phone), the fastening system needs to be quite thin. To date, the prior art self-mating fastener systems have been relatively thick, making them unsuitable to many personal electronics battery bonding applications. For example, U.S. Pat. No. 7,340,807 (Dais et. al.) mentions that the closure elements of one side of a fastening system being 0.035″ thick (889 μm). With two backings, such a design could easily result in a mated pair having a thickness in excess of 1000 μm. U.S. Pat. No. 6,687,962 (Clarner et. al.) discusses the combined fastener thickness of a self-mating closure system of around 1.5-2 mm (1500-2000 μm). Reclosable fastener SJ4570, sold by 3M of St. Paul, Minn. under the Dual Lock brand, is considered low profile yet has a mated thickness, not including adhesive layers, of 98 mils (2389 μm). In contrast, total mated thickness for electronics battery bonding applications in some embodiments to be less than 250 μm, and even more ideally 200 μm. Mated thickness, as the term is used herein, refers to the total thickness of the two lengths of fastener tape when their respective fastening elements have been interengaged, as by sufficiently pressing the two lengths of fastener tape together with sufficient force to cause them to interengage. Mated thickness, as such term is used herein, includes the backing thickness of the two lengths of tape and an adhesive layer on the side opposite the fastener elements (in reference to FIG. 1B, mated thickness is Z1+Z4*2) if such adhesive layers are present, and unless otherwise noted. Some embodiments may include a hot melt adhesive or other hot melt technology integrated into the backing, thereby not requiring further adhesive layers.

In reference to FIG. 1b, for electronic component bonding applications, useful dimensions for closure systems are as follows: a useful distance Z1 is in a range from 60 to 160 μm. A useful distance Z4 is in a range from 17 to 47 μm. A useful distance X4 is in a range from 52 μm to 167 μm. A useful distance X8 is in a range from 58 to 166 μm. Some useful distances X3 and X5 are in a range from 36 to 135 μm.

FIG. 19 shows the resulting battery stack 550 within electronic device shown in in FIG. 18. An adhesive layer (not shown) adhesively couples fastener length 525 to a first major surface of chassis 501. An adhesive layer (not shown) adhesively couples fastener length 510 to a first major surface of battery 520. The two fasteners have been pressed together and are held mechanically bonded by the rail and post system described above. Total thickness for this fastening system, Tz, is between 200-400 μm, including about 200 μm, 225 μm, 250 μm, 275 μm, 300 μm, 325 μm, 250 μm, 375 μm, and 400 μm. If the component were other than a battery, the resulting stack would look similar, with the component taking the place of battery 520.

The fastener system as shown in FIGS. 18 and 19 is reclosably fastenable, meaning that the closure strips may be repeatedly interengaged and disinterengaged through the use of manual force many times. Many times means at least two times, at least 5 times, at least 10 times, or even more. It is this property of the closure system that gives rise to the reworkability of components positioned using this technology.

Thin fasteners suitable for bonding of electronic components, as described herein (that is, reclosable, self-mating fasteners having a mated thickness of between about 200 and 400 μm, between about 200 and 350 μm, between about 200 and 300 μm, between about 225 and 400 μm, between about 225 and 350 μm, between about 250 and 350 μm, between about 250 and 300 μm, between about 250 and 400 μm, between about 300 and 400 μm.

Where the total mated thickness of about 200 μm, the fastening system has about a 50 μm backing, with 100 μm posts extending therefrom. The posts are capped using known processes, adapted for higher tolerances (for example, various rollers used in the manufacturing process may require lower diameters). The capping process reduces the heights of the posts by about 50%, resulting in a backing plus fastener element (Z1 in FIG. 1B) of about 100 μm. Assuming a thing PSA applied to the side of the backing opposite the side having fastener elements of about 25 μm, the total mated thickness would be right around 200 μm (25 μm first PSA layer, 50 μm first backing, 50 μm interengaged fastening elements, 50 μm second backing, 25 μm second PSA layer).

### EXAMPLES

T-Peel Test Method

The force to open values for a self-mating fastener can be determined utilizing ASTM D1876 (designation D1876-08(2015)e1). In general, a standard T-Peel test as defined by ASTM D1876 is performed at an extension rate of 12-inches per minute (30.5 cm/minute) on a representative sample in both the machine and cross web directions and can be utilized to determine whether the closure is in the open or closed configuration. For example, as shown in FIG. 6, the cross web direction is parallel to the vertical seam 138 of the bag 100, and the machine direction is orthogonal to the vertical seam 138.

T-Peel was measured using strips that were 14 inches (35.6 cm) long in the machine direction and having the widths described below. Each strip was folded in half and self-mated to provide a specimen. A calibrated 11.5-pound (5.22 kg) stainless steel roller was used to roll down the specimen. The roller was applied for a full round trip back and forth on each side of the specimen. The ends of the specimen were peeled open so that one inch (2.54 cm) was separated on each end. The separated portions were bent perpendicular to the specimen plane for clamping in the grips of the Instron machine. A cross-head speed of 12-inches per minute (30.5 cm/minute) was used to peel open the specimen over a distance of 4.5 inches (11.4 cm). Three replicates were used per specimen.

Force to Close Test Method

The force required to close a fastener was measured by pulling an open strip of closure device through a set gap, at a rate of 12 in/minute (30.5 cm/minute). Either side of the gap was composed of a radial piece of PTFE to minimize friction while maintaining said gap. A multi-directional load cell is utilized to measure the force normal and tangential to the closure device. The average kinetic peel force is obtained by averaging the force 1 inch (2.54 cm) after closure begins and 1 inch (2.54 cm) before closure ends. This measurement is repeated for a total of 3 measurements, which are then averaged.

Utilizing the Force to Close Test Method, the tactile response to a fastener can be obtained by calculating the average amplitude between the first 50 peaks and the first 50 troughs of the kinetic peel force curve.

Flexural Stiffness Test Method

ASTM D790 (2003) is utilized to measure the flexural rigidity of a specimen. A universal testing machine is used with a 3-point bend fixture. The test specimens were closed, flattened, and placed in the 3-point bend fixture. The gap between the bottom 2 points is set to 12 mm and the force to displace the sample a set distance is measured. The upper compression point diameter was 4 mm, and the support diameters were 5 mm. The upper compression point is advanced at a linear rate of 12 in/minute (30.5 cm/minute). Flexural stiffness is derived from the first primary slope of the force versus displacement curve before the fastening elements slip and begin to slide past one another resulting in a second primary slope.

### Example 1

A twin screw 40-mm extruder was used to extrude a food grade MDPE (medium density polyethylene) obtained from Dow Chemical USA, Inc., under the trade designation Dowlex 2027G″. A 1.5-inch (3.8-cm) single screw extruder was used to extrude a combination of 70% by weight of the “VISTAMAXX 3980FL” Performance Polymer and 30% by weight of a low-density polyethylene obtained from The Dow Chemical Company, Midland, Mich., under the trade designation “DOW LDPE 722”. Both feed streams were introduced to a die manifold on the top of a flat sheet die manufactured by Cloeren Inc., Orange, Tex. Molten polymer was extruded nominally at 220° C. from the flat sheet die as a sheet into a rolling cast extrusion takeaway nip with a rubber roll and a tooling roll with the layer including the 100% by weight food grade MDPE against the tooling roll and the layer including 70% by weight “VISTAMAXX 3980FL” Performance Polymer against the rubber roll. The rubber roll forced the molten polymer into the tooling roll having a nominal surface temperature of 50° C. to 75° C. The molten polymer solidified on the roll, and the structured film was removed from the molding roll after a 180-degree wrap from the rubber roll nip point as described by U.S. Pat. No. 6,106,922 (Cejka). The tool roll had a combination of cavities for providing rail segments and cavities for providing posts having different heights, with the cavities providing the rail segments being deeper than the cavities providing the posts.

The rail segments were capped using the method described in U.S. Pat. No. 5,868,987 (Kampfer) to produce caps having peaks and grooves. The web was slit into strips having a width of 13 mm. When tested by hand by folding a strip onto itself, the fastener was easy to close and had sufficient resistance to peel open. Dimensions of the fastener are provided in Table 1, below.

### Example 2

The web made in Example 1 was further subjected to the method described in U.S. Pat. No. 6,132,660 (Kampfer) to deform the caps and turn a portion of the caps downward toward the backing. The resulting self-mating fastener had an appearance shown in FIG. 17, with dimensions listed in Table 1, below. The image shown in FIG. 17 was obtained from an Analytical Scanning Electron Microscope, Model #JSM-6010LA. Part of the web was slit into strips having a width of 13 mm, and part of the web was slit into strips having a width of 9 mm. When a 13-mm strip of the self-mating fastener was folded over onto itself as shown in FIG. 2C, it had a thickness of less than 30 mil (762 micrometers). When tested by hand, the fastener was easy to close and had resistance to peel open sufficient to hold contents in a bag without spilling.

The layer on the smooth side was thermally activated using high-temperature impingement air at 200° C. as described in U.S. Pat. No. 9,126,224 (Biegler) and U.S. Pat. No. 8,956,496 (Biegler) and bonded to a 5-layer printed polyolefin packaging film without impacting the quality of the printing and with minimal to no visible film distortion. The high-temperature impingement air was directed to both the layer on the smooth side of the fastener and to one side of the polyolefin packaging film. The bond strength between the fastener and the packaging film was deemed adequate since cohesive failure in the layers of the packaging film was observed when removal of the fastener was carried out by hand.

Fifteen 13-mm strips were sampled from different zones of the web. These specimens were evaluated according to the T-Peel Test Method described above. The T-peel test was carried out in the machine direction (MD) of the specimens. For the 15 13-mm samples, the mean maximum load was 0.424 N, with a standard deviation of 0.055 N, and the mean average load was 0.302 N, with a standard deviation of 0.052 N.

### Example 3

Example 3 was prepared as described in Example 1 with the modification that 100% food grade medium density polyethylene obtained from The Dow Chemical Company under the trade designation “DOWLEX 2027G MDPE” was substituted with a 90% polypropylene from Total under trade name 3571 and 10% “VISTAMAXX 3980FL” Performance Polymer. A capping roll having a smooth surface was used to produce smooth caps instead of the caps having peaks and grooves. The caps had an appearance such as that shown in FIG. 1A. The self-mating closure was also bonded to a printed polyolefin packaging film as described in Example 2 with no damage or wrinkling of the oriented printed packaging film. The bond strength between the fastener and the packaging film was deemed adequate as upon removal of the bonded fastener from the packaging film, cohesive failure in the layers of the packaging film was observed.

### Example 4

Before being bonded to the packaging film, the web made in Example 3 was further subjected to the method described in U.S. Pat. No. 6,132,660 (Kampfer) to deform the caps and turn a portion of the caps downward toward the backing. The resulting self-mating fastener had an appearance shown in FIGS. 2A to 2C, with dimensions listed in Table 1, below. Part of the web was slit into strips having a width of 13 mm, and part of the web was slit into strips having a width of 9 mm. When a 13-mm strip of the self-mating fastener was folded over onto itself as shown in FIG. 2C, it had a thickness of less than 30 mil (762 micrometers).

Six 13-mm strips were sampled from three different zones of the web in the cross-direction, one toward each edge and one toward the center of the web. Two strips were sampled from each zone. Similarly, eighteen 9-mm strips were sampled from the three zones, six from each zone. These specimens were each evaluated using the Force to Close Test Method described above. The maximum and minimum kinetic peel force to close at 12 inches per minute from the set of specimens were 0.079 N and 0.020 N, respectively, with maximum and minimum average kinetic peel oscillation amplitude of 0.028 N and 0.013 N, respectively. When the data were normalized against the two different widths, the maximum and minimum kinetic peel force to close at 12 inches per minute from the set of specimens were 0.070 N and 0.023 N, respectively, with maximum and minimum average kinetic peel oscillation amplitude of 0.031 N and 0.0002 N, respectively.

Six 13-mm strips and eighteen 9-mm strips were sampled from the three different zones of the web as described above. These specimens were each evaluated using the Flexural Stiffness Test Method described above. For these specimens, the flexural rigidity ranged from 221.7 mN/mm to 1149.3 mN/mm with an average of 601.0 mN/mm and a standard deviation of 221.7 mN/mm. The reported flexural rigidity was the slope of the first leg of the force vs displacement curve from the 3 point bend before the rail segments begin to slide against one another. None of the specimens was observed to open during the 3 point bend.

Fifteen 13-mm strips were sampled from different zones of the web. These specimens were evaluated according to the T-Peel Test Method described above. The T-peel test was carried out in the machine direction (MD) of the specimens. For the 15 13-mm samples, the mean maximum load was 0.511 N, with a standard deviation of 0.072 N, and the mean average load was 0.339 N, with a standard deviation of 0.056 N.

Sixteen 9-mm strips were sampled from different zones of the web. These specimens were evaluated according to the T-Peel Test Method described above. The T-peel test was carried out in the machine direction (MD) of the specimens. For the 18 9-mm samples, the mean maximum load was 0.562 N, with a standard deviation of 0.062 N, and the mean average load was 0.351 N, with a standard deviation of 0.049 N.

TABLE 1

| | A1 | A2 | Z1 | Z2 | Z3 | Z4 | Z5 | Z6 | Z1-Z2 | Z1 + Z4 |
|---|---|---|---|---|---|---|---|---|---|---|
| | (μm) | (μm) | (μm) | (μm) | (μm) | (μm) | (μm) | (μm) | (μm) | (μm) |
| Ex. 1 | | | | | | | | | | |
| Avg | 95 | 101 | 377 | 305 | 346 | 113 | 20 | 22 | 71 | 490 |
| Std | 1.0 | 0.4 | 11.1 | 12.1 | 6.7 | 9.4 | 1.5 | 1.5 | 17.2 | 15.5 |
| Ex. 2 | | | | | | | | | | |
| Avg | 101 | 100 | 386 | 279 | 337 | 104 | 20 | 32 | 107 | 490 |
| Std | 2.4 | 1.7 | 11.8 | 18.7 | 19.9 | 5.2 | 2.0 | 2.9 | 27.1 | 9.5 |
| Ex. 3 | | | | | | | | | | |
| Avg | 99 | 105 | 419 | 357 | 373 | 111 | 19 | 28 | 62 | 530 |
| Std | 1.5 | 0.8 | 11.1 | 28.4 | 13.2 | 4.0 | 1.6 | 2.9 | 27.8 | 10.2 |
| Ex. 4 | | | | | | | | | | |
| Avg | 95 | 91 | 443 | 356 | 359 | 116 | 19 | 39 | 86 | 559 |
| Std | 1.3 | 2.0 | 15.0 | 19.4 | 10.6 | 4.7 | 4.3 | 10.6 | 24.7 | 17.4 |
| Ex. 6 | | | | | | | | | | |
| Value | — | — | 208.5 | 89.5 | — | 92.8 | — | — | 119.0 | 301.4 |
| Ex. 7 | | | | | | | | | | |
| Value | — | — | 101.9 | 53.1 | — | 95.5 | — | — | 48.8 | 197.4 |
| Ex. 8 | | | | | | | | | | |
| Value | 31.5 | 33.5 | 125.0 | 101.2 | 114.8 | 37.5 | 6.6 | 7.3 | 23.9 | 162.5 |

| | X1 | X2 | X3 | X4 | X5 | X6 | X7 | Y1 | Y2 | Y3 | Y4 | Y5 |
|---|---|---|---|---|---|---|---|---|---|---|---|---|
| | (μm) | (μm) | (μm) | (μm) | (μm) | (μm) | (μm) | (μm) | (μm) | (μm) | (μm) | (μm) |
| Ex. 1 | | | | | | | | | | | | |
| Avg | 139 | 134 | 297 | 392 | 247 | 121 | 1051 | 688 | 117 | 139 | 511 | 67 |
| Std | 3.5 | 3.5 | 7.4 | 4.6 | 16.8 | 16.0 | 9.6 | 0.8 | 5.6 | 9.1 | 4.7 | 8.4 |
| Ex. 2 | | | | | | | | | | | | |
| Avg. | 134 | 135 | 310 | 388 | 219 | 116 | 701 | 671 | 119 | 154 | 524 | 64 |
| Std | 1.5 | 3.4 | 24.6 | 11.4 | 8.0 | 25.0 | 443.9 | 9.7 | 2.0 | 6.8 | 7.7 | 4.0 |
| Ex. 3 | | | | | | | | | | | | |
| Avg | 132 | 129 | 238 | 427 | 277 | 147 | 1064 | 686 | 115 | 173 | 531 | 60 |
| Std | 3.2 | 5.2 | 23.1 | 23.4 | 29.4 | 20.6 | 5.7 | 11.0 | 11.2 | 9.9 | 5.0 | 6.8 |
| Ex. 4 | | | | | | | | | | | | |
| Avg | 133 | 135 | 292 | 351 | 322 | 113 | 1060 | 638 | 114 | 212 | 538 | 49 |
| Std | 2.3 | 3.4 | 13.4 | 21.1 | 33.7 | 16.2 | 11.9 | 14.9 | 7.2 | 12.6 | 3.0 | 6.0 |
| Ex. 6 | | | | | | | | | | | | |
| Value | 280.2 | — | — | 435.4 | — | — | — | — | — | — | — | — |
| Ex. 7 | | | | | | | | | | | | |
| Value | 74.3 | — | — | 161.3 | — | — | — | — | — | — | — | — |
| Ex. 8 | | | | | | | | | | | | |
| Value | 46.1 | 44.4 | 98.5 | 130.0 | 81.9 | 40.1 | 348.6 | 228.2 | 38.8 | 46.1 | 169.5 | 22.2 |

Dimensions refer to FIGS. 1B and 1C, Avg=Average, Std=Standard Deviation. Each average is of 5 measurements. Data was obtained with a Keyence Digital Microscope, Model VHX-600.

### Example 5

To assess whether fastening member designs can be in the fastened and unfastened configurations one or more times without destroying the functionality of the fastener, a Finite Element Model (FEM) was developed to capture the effects of system deformation on plastic strain generation in the features. The commercial code Abaqus 2017 by Simulia was utilized to facilitate modeling tasks. A Standard analysis method was utilized to capture steady state deformation results without considering inertial effects. Two representative units of fastening members were placed in an unfastened configuration, then displaced towards one another until full engagement occurred. A frictionless contact definition was established at the physical interface of the two fastening member units. An elastic-plastic material definition was utilized with a Young's Modulus of 21,755 psi, a Poissons' ratio of 0.33, a plastic yield strain of 10.6%, a yield stress of 2320 psi, an ultimate strain of 50% and an ultimate stress of 2900 psi. The strain results at nodes dispersed throughout the deformable mesh were monitored for a transition into plastic strain (irreversible deformation). Log Strain (True Strain) results of a Finite Element Model of a representative rail and post construction are shown in FIG. 3A. Strain contours are illustrated on the surface ranging from a minimum strain (white) to a maximum strain (black). FIG. 3A shows the fastening system construction in its maximum deformation state with 11.19% strain. FIG. 3B shows the fastening system construction in its final fastened state with a maximum residual strain of 0.69%.

### Illustrative Example A

A FEM was developed using the definitions of Example 5. Similar fastening features were used in this model in a capped rail to capped rail system construction. The fastening features are illustrated in FIG. 4 in their final fastened state. The nominal strain state in the final fastened configuration results in 20.15% permanent plastic deformation, which may reduce the fastener's useful lifetime.

### Example 6

A 1.5-inch (3.8-cm) single screw extruder was used to extrude a combination of 78% by weight of “D180M” homopolymer polypropylene, available from Braskem, Sao Paulo Brazil, and 22% by weight of Adflex Polyolefin, from LyondellBasell Industries N.V London UK, under the trade designation “Adflex V109F Polyolefin”. The feed stream was introduced to a die manifold on the top of a flat sheet die manufactured by Cloeren Inc., Orange, Tex. Molten polymer was extruded nominally at 220° C. from the flat sheet die as a sheet into a rolling cast extrusion take-away nip with a rubber roll and a tooling roll. The rubber roll forced the molten polymer into the tooling roll having a nominal surface temperature of 50° C. to 75° C. The molten polymer solidified on the roll, and the structured film was removed from the molding roll after a 180-degree wrap from the rubber roll nip point as described by U.S. Pat. No. 6,106,922 (Cejka). The tool roll had post structures of consistent 584 micrometers (μm) depth on the surface in an ordered pattern resembling a scaled down pattern utilized by commercially available re-closable fastener SJ4570, sold by 3M of St. Paul, Minn. under the Dual Lock brand. This array is described in U.S. Pat. No. 3,408,705A.

The posts were capped using a timed heat and pressure Swinger press (Air Operated Automatic DC16AP 14×16 digital swinger from Geo Knight & Co Inc, St Brockton Mass. USA) in a piece wise approach. The press was set to a temperature of 325° F., 30 psi air pressure, and held for 5 seconds. The web was slit into strips having a width of 13 mm and a length of 50 mm. When tested by hand by folding a strip onto itself, the fastener was closed using a rigid rod rolled over the closure and had enough resistance to peel open. Dimensions of the final fastening elements were Z1=208.54 μm, Z2=89.53 μm, Z4=92.81 μm, X1=280.18 μm and X4=435.41 μm, resulting in a total mated thickness of 394 μm.

### Example 7

Microchannel fluid control films were prepared by extrusion, embossing a low-density polyethylene polymer (DOW955i) onto a cylindrical tool according to the process described in U.S. Pat. No. 6,372,323 (Kobe). The tool was prepared by diamond turning the pattern of grooves shown in FIG. 2B in negative relief. The grooves were cut at a helix angle of 80 degrees relative to the cylinder axis, producing films with channels oriented at 20 degrees relative to the longitudinal (down web) direction of the film, as described in US 2017/0045285 A1 (Halverson). The polymer was melted in an extruder at 365° F. and passed through a die into a nip between the tool roll heated to 200° F. and Smooth 70° F. backup roll using a nip pressure of 500 psi. The extruder speed and tool rotation speed were adjusted to produce a film with an overall thickness of 210 microns.

The embossed structure was capped using a timed heat and pressure Swinger press (Air Operated Automatic DC16AP 14×16 digital swinger from Geo Knight & Co Inc, St Brockton Mass. USA) in a piece wise approach. The press was set to a temperature of 350° F., 30 psi air pressure, and held for 5 seconds. The web was slit into strips having a width of 13 mm and a length of 13 mm. When tested by hand by folding a strip onto itself, the fastener was closed using a rigid rod rolled over the closure and had enough resistance to peel open. Dimensions of the final post structures were Z1=101.9 μm, Z2=53.1 μm, Z4=95.5 μm, X1=74.3 μm and X4=161.3 μm, resulting in a total mated thickness of 293 μm.

This array offers a one direction sliding film which could be used to limit an electronic component's motion in an electronics device yet enables disengagement and removal of the component at end of life.

### Example 8

To assess whether fastening member designs can be in the fastened and unfastened configurations one or more times without destroying the functionality of the fastener, a Finite Element Model (FEM) was developed with the same commercial code, boundary conditions, and material properties of Example 5 to capture the effects of system deformation on plastic strain generation in the features for a construction with a total mated thickness of 200 microns. The rest of dimensions utilized are included in Table 1. The strain results at nodes dispersed throughout the deformable mesh were monitored for a transition into plastic strain (irreversible deformation). The plastic strain performance of this system was similar to Example 5, illustrating the scalability of this fastening system. The closure forces were similar for the overall smaller unit cell. In Example 5, an average closure pressure of 15.72 psi was calculated. In Example 8, an average closure pressure of 15.96 psi was calculated. The fastening system construction in its maximum deformation state exhibited a 6.3% strain. The fastening system construction in its final fastened state exhibited a maximum residual strain of 0.0%.

Various modifications and alterations of this disclosure may be made by those skilled in the art without departing from the scope and spirit of the disclosure, and it should be understood that this disclosure is not to be unduly limited to the illustrative embodiments set forth herein. All patents and patent applications cited above are hereby incorporated by reference into this document in their entirety.

1.-31. (canceled)

32. An electronic device comprising:
a chassis;
an electronic component; and
a self-mating, releasably fastenable fastening system mechanically coupling the chassis and the electronic component,
wherein the fastening system has a total mated thickness of between 200 μm and 400 μm.

33. The electronic device of claim 32, wherein releasably fastenable means that the fastening elements can alternate between fastened and unfastened configurations at least two times without destroying the functionality of the fastener.

34. The electronic device of claim 32, wherein the total mated thickness of the fastening system comprises the thickness of a first and second strips of fastener material each having fastener elements extending outward from a first major side of a backing with the other side having an adhesive layer disposed thereon, wherein the first and second strips are mechanically interengaged with one another, and wherein the total mated thickness includes the adhesive layers on both strips.

35. The electronic device of claim 32, wherein the fastening system comprises first and second closure strips, which both comprise a polymeric backing having fastening elements in a first pattern extending from a first major side thereof and an adhesive coating on a second major side thereof.

36. The electronic device of claim 35, wherein the second major side of the first closure strip is adhesively coupled to the chassis, and the second major side of the second closure strip is adhesively coupled to the electronic component, and wherein the fastener elements of the first and second closure strips are mechanically interengaged.

37. The electronic device of claim 36, wherein the self-mating fastening system prevents movement of the component in X, Y, or Z dimensions relative to the chassis.

38. The electronic device of claim 36, wherein the first pattern comprises:
rows of rail segments and rows of posts protruding perpendicularly from the backing, wherein the rows of rail segments and rows of posts alternate,
wherein each of the rail segments has a base portion attached to the backing and a cap portion distal from the backing, wherein the cap portion has a cap width that is greater than a width of the base portion, wherein the cap portion overhangs the base portion on opposing sides, wherein the base portion has a length that is greater than the width of the base portion, and wherein each of the posts has a height that is no greater than a height of the rail segments and a length that is different from the length of the rail segments.

39. The electronic device of claim 38, wherein a ratio of the length of the base portion to the width of the base portion is at least 1.5:1.

40. The electronic device of claim 38, wherein the thickness of the backing combined with the height of the rail segments is up to 220 μm.

41. The electronic device of claim 38, wherein a number of posts in one of the rows of posts is more than a number of rail segments in one of the rows of rail segments.

42. The electronic device of claim 38, wherein the length of the base portion of the rail segments is greater than a length of the posts.

43. The electronic device of claim 38, wherein each of the posts has at least one of a height-to-width aspect ratio that is at least 1.5:1 or a height-to-length aspect ratio that is at least 1.5:1.

44. The electronic device of claim 38, wherein the posts have a lower bending stiffness than the rail segments.

45. The electronic device of claim 32, wherein the electronic component comprises a battery.

46. A fastener system comprising:
a self-mating, releasably fastenable fastening system having a total mated thickness of between 200 μm and 400 μm.

47. The fastener system of claim 46, wherein the fastening system comprises first and second closure strips each comprising a backing having fastener elements extending from a first major side thereof and an adhesive layer on the second major side of the backing opposite the first major side, and wherein the fastener elements of the first closure strip are interengaged with the fastener elements of the second closure strip.

48. The fastener system of claim 46, wherein the fastening system comprises first and second closure strips, which each comprise a polymeric backing having fastening elements in a first pattern extending from a first major side thereof and an adhesive coating on a second major side thereof.

49. The fastener system of claim 48, wherein the first pattern comprises:
rows of rail segments and rows of posts protruding perpendicularly from the backing, wherein the rows of rail segments and rows of posts alternate,
wherein each of the rail segments has a base portion attached to the backing and a cap portion distal from the backing, wherein the cap portion has a cap width that is greater than a width of the base portion, wherein the cap portion overhangs the base portion on opposing sides, wherein the base portion has a length that is greater than the width of the base portion, and wherein each of the posts has a height that is no greater than a height of the rail segments and a length that is different from the length of the rail segments.

50. A component of a self-mating fastener system, comprising:
a polymeric backing having first and second major sides, with fastening elements extending outward from a first major side of the backing, and an adhesive coating on the second major side of the backing, wherein the thickness of the adhesive layer, the backing, and the fastening elements is between about 125 μm to about 200 μm; and,
wherein the fastening elements are self-mating and releasably fastenable.

51. The component of claim 50, wherein the fastening elements are arranged in a first pattern, wherein the first pattern comprises:
rows of rail segments and rows of posts protruding perpendicularly from the backing, wherein the rows of rail segments and rows of posts alternate,
wherein each of the rail segments has a base portion attached to the backing and a cap portion distal from the backing, wherein the cap portion has a cap width that is greater than a width of the base portion, wherein the cap portion overhangs the base portion on opposing sides, wherein the base portion has a length that is greater than the width of the base portion, and wherein each of the posts has a height that is no greater than a height of the rail segments and a length that is different from the length of the rail segments.
